(19) United States
(12) Patent Application Publication
(10) Pub. No.: US 2021/0399190 A1
(43) Pub. Date: Dec. 23, 2021

(54) Apparatus Including Thermal Energy Harvesting Thermionic Device, and Related Methods

(71) Applicant: Birmingham Technologies, Inc., Arlington, VA (US)

(72) Inventor: Joseph Birmingham, Arlington, VA (US)

(73) Assignee: Birmingham Technologies, Inc., Arlington, VA (US)

(21) Appl. No.: 16/906,508

(22) Filed: Jun. 19, 2020

(51) Int. Cl. H01L 37/00; H02S 10/10; H02S 40/38

(52) U.S. Cl. CPC H01L 37/00; H02S 40/38; H02S 10/10

(57) ABSTRACT

Embodiments relate to a method in which electrical energy is supplied to a heat generating source to convert the electrical energy to heat. A thermal energy harvesting thermionic device proximal to the heat generating source to receive the heat from the heat generating source is heated and an electrical output is generated. The thermal energy harvesting thermionic device includes at least a cathode, an anode spaced from the cathode to provide an inter-electrode gap between the cathode and the anode, and a plurality of nanoparticles suspended in a fluid medium contained in the inter-electrode gap. The temperature of the thermal energy harvesting thermionic device is monitored, and a source of the electrical energy is activated to supply the electrical energy to the heat generating source in response to a change in the temperature of the thermal energy harvesting thermionic device. Also provided are related apparatus.

### BACKGROUND

The present embodiments relate to an apparatus including a thermal energy harvesting thermionic device operating with one or more additional components to charge a power storage device, such as a rechargeable battery or secondary cell, and/or to provide electricity to an electrical load, such as a portable electronic device (e.g., a phone, computer, etc.) or other power-consumption device. Also provided are related systems and methods, including methods of making and using the apparatus.

Various consumer and commercial goods, such as mobile phones, laptop and tablet computers, portable electronic products, and vehicles are powered in whole or in part (e.g., hybrid vehicles) by batteries. While many batteries possess advantageous attributes, such as re-chargeability, portability, light weight, and compactness, electrochemical batteries also have drawbacks. Even the most advanced electrochemical batteries have limited charge cycles and are subject to degradation that adversely affects charge retention capacity, power, and efficiency. Thus, batteries are susceptible to being drained of charge at extremely inconvenient times, such as while accompanying a user on a road trip between re-charging stations in the case of a vehicle or during extensive air or sea travel. The loss of battery charge in such circumstances can be much more than a mere inconvenience, especially in emergency situations, particularly when the battery is used to power mobile phones and computers, among other goods.

### SUMMARY

The embodiments include apparatus, systems, and methods that include a thermal energy harvesting thermionic device, particularly for charging a secondary power source and/or providing electrical energy (e.g., electricity) to an electrical load, such as a power-consumption device.

In an aspect, an apparatus is provided that includes an electrical energy storage device, a heat generating source, a thermal energy harvesting thermionic device, a temperature sensor, and a controller. The heat generating source is operatively connected to the electrical energy storage device to convert electrical energy supplied by the electrical energy storage device to heat. The thermal energy harvesting thermionic device is proximal to the heat generating source to receive the heat from the heat generating source and generate an electrical output. The thermal energy harvesting thermionic device includes at least a cathode, an anode spaced from the cathode to provide an inter-electrode gap between the cathode and the anode, and a plurality of nanoparticles suspended in a fluid medium contained in the inter-electrode gap. The nanoparticles are arranged in the inter-electrode gap to permit ion transfer between the cathode and the anode. The temperature sensor is configured to monitor a temperature of the thermal energy harvesting thermionic device. The controller is operatively connected to the electrical energy storage device and the temperature sensor to activate the electrical energy storage device to supply the electrical energy to the heat generating source in response to the temperature of the thermal energy harvesting thermionic device, as measured by the temperature sensor, falling below a threshold temperature.

In another aspect, an apparatus is provided that includes a photovoltaic cell, a heat generating source, a thermal energy harvesting thermionic device, and a temperature sensor. The photovoltaic cell is configured to convert light energy into electrical energy. The heat generating source is operatively connected to the photoelectric cell to convert electrical energy supplied by the photoelectric cell to heat. The thermal energy harvesting thermionic device is proximal to the heat generating source to receive the heat from the heat generating source and generate an electrical output. The thermal energy harvesting thermionic device includes at least a cathode, an anode spaced from the cathode to provide an inter-electrode gap between the cathode and the anode, and a plurality of nanoparticles suspended in a fluid medium contained in the inter-electrode gap. The nanoparticles are arranged in the inter-electrode gap to permit ion transfer between the cathode and the anode. The temperature sensor is configured to monitor a temperature of the thermal energy harvesting thermionic device. The controller is operatively connected to the photovoltaic cell and the temperature sensor to activate the photovoltaic cell to supply the electrical energy to the heat generating source in response to the temperature of the thermal energy harvesting thermionic device, as measured by the temperature sensor, falling below a threshold temperature.

In yet another aspect, a method is provided in which electrical energy is supplied to a heat generating source to convert the electrical energy to heat. A thermal energy harvesting thermionic device proximal to the heat generating source to receive the heat from the heat generating source is heated and an electrical output is generated. The thermal energy harvesting thermionic device includes at least a cathode, an anode spaced from the cathode to provide an inter-electrode gap between the cathode and the anode, and a plurality of nanoparticles suspended in a fluid medium contained in the inter-electrode gap. The temperature of the thermal energy harvesting thermionic device is monitored, and a source of the electrical energy is activated to supply the electrical energy to the heat generating source in response to a change in the temperature of the thermal energy harvesting thermionic device, as measured by the temperature sensor, falling below a threshold temperature.

Other aspects disclosed herein include systems, devices, components, apparatus, methods, and processes. Features of these and other aspects will become apparent from the following detailed description of exemplary embodiments, taken in conjunction with the accompanying drawings.

### BRIEF DESCRIPTION OF THE SEVERAL VIEWS OF THE DRAWINGS

The drawings referenced herein form a part of the specification. Features shown in the drawings are meant as illustrative of only some embodiments, and not of all embodiments, unless otherwise explicitly indicated.

FIG. 1 depicts a block diagram of an apparatus including an electrical energy storage device, a thermal energy harvesting thermionic device, and a rechargeable power storage device, with the re-chargeable power storage device operatively connected to an electrical load embodied as a power-consumption device according to an exemplary embodiment.

FIG. 2 depicts a block diagram of an apparatus including an electrical energy storage device and a thermal energy harvesting thermionic device, with the thermal energy harvesting thermionic device operatively connected to a re-chargeable power storage device of an electrical load embodied as a power-consumption device according to another exemplary embodiment.

FIG. 3 depicts a block diagram of an apparatus including an electrical energy storage device and a thermal energy harvesting thermionic device, with the thermal energy harvesting thermionic device operatively connected to a re-chargeable power storage device, which is in turn operatively connected to an external electrical load embodied as a power-consumption device according to still another exemplary embodiment.

FIG. 4 depicts a block diagram of an apparatus including an electrical energy storage device and a thermal energy harvesting thermionic device, with the thermal energy harvesting thermionic device operatively connected to a load embodied as a power-consumption device according to yet another exemplary embodiment.

FIG. 5 depicts a block diagram of an apparatus associated with a photovoltaic cell and including a thermal energy harvesting thermionic device and a re-chargeable power storage device, with the rechargeable power storage device operatively connected to an electrical load embodied as a power-consumption device according to an exemplary embodiment.

FIG. 6 depicts a block diagram of an apparatus associated with a photovoltaic cell and including a thermal energy harvesting thermionic device, with the thermal energy harvesting thermionic device operatively connected to a re-chargeable power storage device of an electrical load embodied as a power-consumption device according to a further exemplary embodiment.

FIG. 7 depicts a block diagram of an apparatus associated with a photovoltaic cell and including a thermal energy harvesting thermionic device, with the thermal energy harvesting thermionic device operatively connected to an external re-chargeable power storage device, which is in turn operatively connected to an electrical load embodied as a power-consumption device according to a still further exemplary embodiment.

FIG. 8 depicts a block diagram of an apparatus associated with a photovoltaic cell and including a thermal energy harvesting thermionic device, with the thermal energy harvesting thermionic device operatively connected to a load embodied as a power-consumption device according to still another exemplary embodiment.

FIG. 9 is a circuit diagram of a charging system for charging a re-chargeable power storage device according to an exemplary embodiment.

FIG. 10 depicts a sectional view of a thermal energy harvesting thermionic device according to an exemplary embodiment.

FIG. 11A depicts a transparent top view of an embodiment of a spacer and adjacent electrodes for use in a thermal energy harvesting thermionic device.

FIG. 11B depicts a transparent top view of an embodiment of a spacer and adjacent electrodes for use in a thermal energy harvesting thermionic device.

FIG. 12 depicts a schematic view of an embodiment of a nano-fluid of a thermal energy harvesting thermionic device, the nano-fluid including a plurality of nanoparticle clusters suspended in a dielectric medium.

FIG. 13 depicts a schematic perspective view of a circuit containing a thermionic power harvesting device, an electrical load or a re-chargeable power storage device, and a dissipating device.

FIG. 14 depicts a perspective view of a thermionic power harvesting device according to an embodiment.

FIG. 15 depicts a perspective view of a first repository of layered materials that may be used to manufacture a thermionic power harvesting device.

FIG. 16 depicts a perspective view of a second repository of layered materials that may be used to manufacture a thermionic power harvesting device.

FIG. 17A depicts an enlarged perspective, sectional and fragmented view of a portion of the thermal energy harvesting thermionic device of FIG. 14

FIG. 17B is a fragmented cross-sectional view of box 17B of FIG. 17A depicting part of the energy harvesting device of FIG. 14.

FIG. 18 is a cross-sectional view of a multi-layer thermionic power harvesting device according to an exemplary embodiment.

FIG. 19 depicts a flowchart illustrating a process for generating electrical power with a thermal energy harvesting thermionic device.

FIG. 20 depicts an electrospray technique suitable for making a thermal energy harvesting thermionic device according to exemplary embodiments.

FIG. 21 depicts a solar cell arranged for placement on an apparatus housing.

FIG. 22 is a graph illustrating current measurements as a function of time and temperature of a thermal energy harvesting thermionic device.

### DETAILED DESCRIPTION OF EXEMPLARY EMBODIMENTS

It will be readily understood that the components and features of the exemplary embodiments, as generally described herein and illustrated in the Figures, may be arranged and designed in a wide variety of different configurations. Thus, the following detailed description of the embodiments of the methods, devices, assemblies, apparatus, systems, compositions, etc. of the exemplary embodiments, as presented in the Figures, is not intended to limit the scope of the embodiments, as claimed, but is merely representative of selected embodiments.

The illustrated embodiments will be best understood by reference to the drawings, wherein like parts are designated by like numerals throughout. The following description is intended only by way of example, and illustrates certain selected embodiments of methods, devices, assemblies, apparatus, systems, etc. that are consistent with the embodiments as claimed herein.

Reference throughout this specification to “a select embodiment,” “one embodiment,” “an exemplary embodiment,” or “an embodiment” means that a particular feature, structure, or characteristic described in connection with the embodiment is included in at least one embodiment. Thus, appearances of the phrases “in a select embodiment,” “in one embodiment,” “in an exemplary embodiment,” or “in an embodiment” in various places throughout this specification are not necessarily referring to the same embodiment. The embodiments may be combined with one another in various combinations and modified to include features of one another.

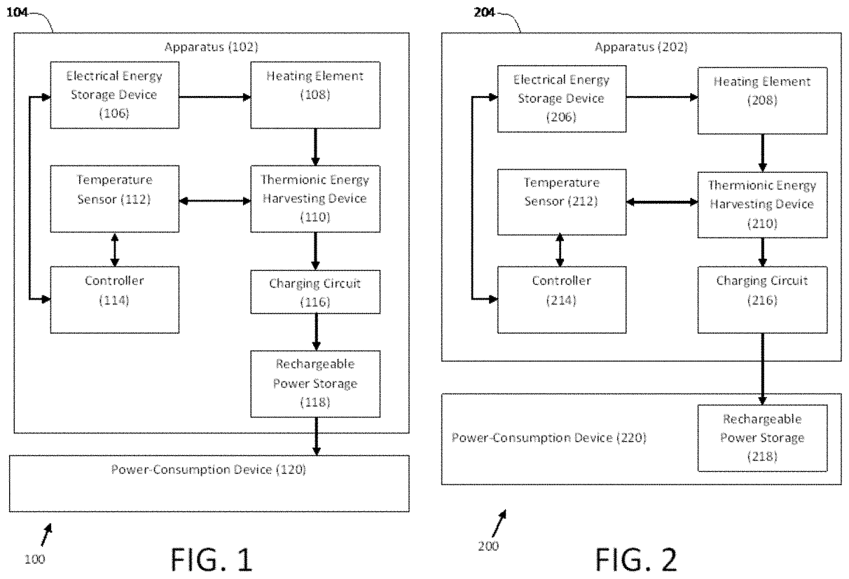

Referring now more particularly to FIG. 1, a block diagram (100) depicts an apparatus (102) for powering a load embodied in FIG. 1 as a power-consumption device (120). The apparatus (102) includes a housing (104) containing an electrical energy storage device (106), a heat generating source (also referred to herein as a heating element) (108), a thermal energy harvesting thermionic device (110), a temperature sensor (112), a controller (114), a charging circuit (116), and a re-chargeable power storage device (118).

Electrical Energy Storage Device (106)

In an exemplary embodiment, one or more capacitors are selected as the electrical energy storage device (106), although other devices capable of storing electrical energy, e.g., a charge, may be used. Unless otherwise indicated, the term capacitor can include supercapacitor, micro-capacitor, micro-supercapacitor, and the like. Examples of electrical energy storage devices that may be used instead of or in combination with one or more capacitors include, without limitation, inductors, fuel cells, non-rechargeable batteries, re-chargeable batteries, and other electrical energy storage elements.

Heating Element (108)

The electrical energy storage device (106), which is shown herein operatively connected to the heating element (108), supplies electrical energy, typically a direct current (DC) voltage or current, to the heating element (108). As current flows from the electrical energy storage device (106) to the heating element (108), the electrical energy is converted by the heating element (108) into heat (or thermal energy).

Heat is the by-product of resistance of a circuit component, including but not limited to resistors. In an exemplary embodiment, the heating element (108) comprises one or more resistors. Various types of resistors may be employed. In an exemplary embodiment, selection or employment of resistors is configurable. For example, resistors suitable for use as the heating element (108) may have a resistance in a range of, for example, about 0.01 ohms to about 10 (k ohms) (10,000 ohms) and/or a power dissipation rating of, for example, about 0.001 watts to about 1 or more megawatts. Other heating elements with low thermal resistance change may be used instead of or in addition to a resistor.

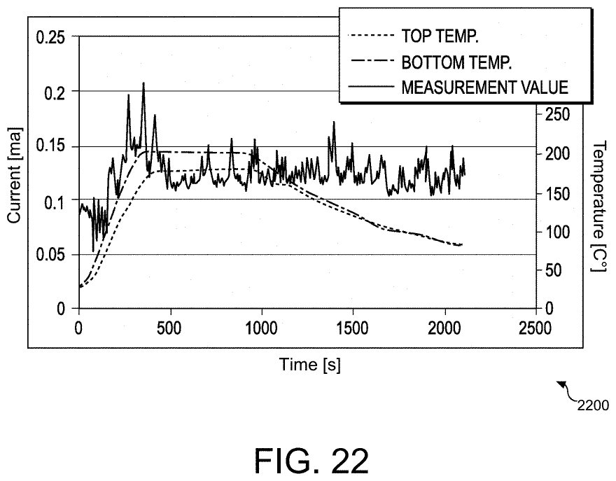

The heating element (108) is positioned proximal to the thermal energy harvesting thermionic device (110) so that the thermal energy generated by the heating element (108) thermally perturbs the thermal energy harvesting thermionic device (110), as discussed in further detail below, including in connection with FIG. 22.

Thermal Energy Harvesting Thermionic Device (110)

The thermal energy harvesting thermionic device (110), which is positioned proximal to the heating element (108), receives the heat or thermal energy from the heating element (108) and generates an electrical output. The thermal energy harvesting thermionic device (110) includes at least a cathode, an anode spaced from the cathode to provide an inter-electrode gap between the cathode and the anode, and a plurality of nanoparticles suspended in a fluid medium contained in the inter-electrode gap. The nanoparticles are arranged in the inter-electrode gap to permit ion transfer between the cathode and the anode.

The thermal energy harvesting thermionic device (110) operates on a thermionic power conversion principle to convert thermal energy supplied by the heating element (108) (and possibly the surrounding environment or other proximal components) into electrical energy by an emission of electrons from the cathode, which is also referred to herein as an emitter electrode. The production of electrons from the cathode is controlled by barriers to the flow of electricity. The first barrier to be overcome involves establishing electron energy that is sufficiently large to exceed the work function of the cathode to enable electron emission from the cathode surface. At lower temperatures, only a fraction of the electrons have sufficient energy to allow thermionic emission to proceed, thus limiting the total current flow. Intermediate temperatures provide higher energy than the lower temperatures, which gives rise to an increase in electron production at the cathode surface due to a larger distribution of electrons with the required energy for emission. As the kinetic energy of the electrons is dependent upon the temperature of the cathode, increasing the temperature of the cathode results in an increase in electron emission, and hence electrical current. In an exemplary embodiment, the thermal energy harvesting thermionic device selects energies with a thermionic barrier.

The electrons emitted from the cathode cool the electrode in a similar way that rain evaporating from roof carries away heat. The “hot” electrons emitted by the cathode in turn heat the anode. This movement of electrons sets up a thermal gradient for a nanoscale heat engine.

Electrons flow from an emitter electrode, across an inter-electrode gap, to the anode, which is also referred to herein as a collector electrode. The anode is spaced from the cathode by the inter-electrode gap. A medium is contained in the inter-electrode gap and is in contact with facing surfaces of the cathode and the anode. According to an exemplary embodiment, the medium contains suspended nanoparticles to permit electron transfer between the cathode and the anode. Thermal processes which involve the transport of the electrons across the electrode gap (without resistively heating the nanofluid) involve the movement of nanoparticles within a nanofluid to come close together or collide with each other and with the surfaces of the electrodes. These collisions enable the hopping or transition of electrons in the direction of the electric field (i.e., current production). (The reverse production of electrons from the anode to the cathode is suppressed by the electric field.) This electric field is supplied by the use of dissimilar electrode metals. The steps in transmitting the electrons across the gap from the cathode (emitter electrode) to the collector (anode electrode) creates a flow of electrical energy, and when connected to a circuit, enables electrons to pass through an electrical load completing the circuit. Although not shown in the accompanying drawings, the electrical current from the thermal energy harvesting thermionic device to the load may be smoothed via, for example, a trimming capacitor.

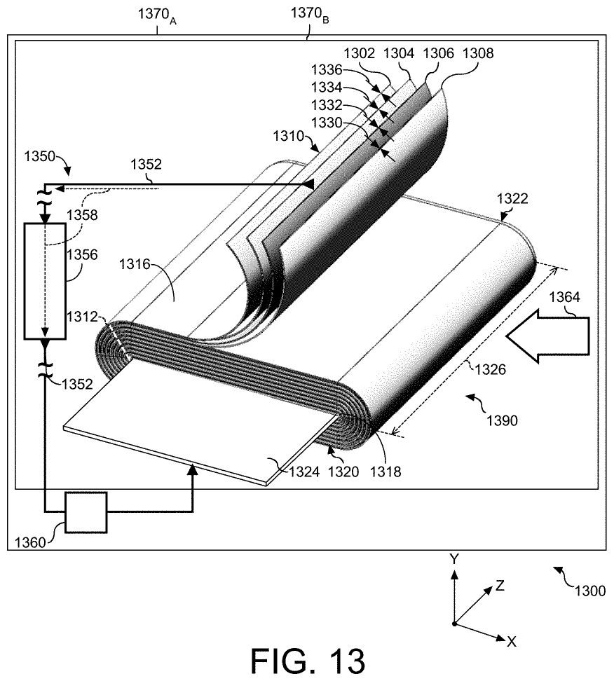

According to an exemplary embodiment, a design feature of an exemplary embodiment of the circuit is that the diameter of the return wire is small enough to transfer heat readily back to the cathode without creating a large resistance. Embodiments for carrying out the thermal transfer are discussed below in connection with FIG. 13. As the temperature or average energy of electrons is reduced due to thermal exchange of heat leaving the anode to a heat dissipating device, such as a heat exchanger or a heat sink, the reduced thermal energy is re-supplied to the cathode to maintain the thermionic harvesting device operating at a high efficiency. In an exemplary embodiment, the heat dissipating device is a microstructured array heat exchanger. This average energy of electrons leaving the anode (collector electrode) is reduced by the heat dissipating device. The returning electrons to the emitter electrode will therefore complete a heat engine cycle with a lower average energy leaving the load than supplied to the load.

As noted, thermal energy causes electrons to flow from the cathode to the anode. Accordingly, the heating element (108) is placed in closer proximity to the cathode than the anode of the thermal energy harvesting thermionic device (110) in an exemplary embodiment.

FIG. 22 is a graph (2200) illustrating the relationship between measured current (milliamps) as a function of time (seconds) and temperature (degrees Celsius) for the thermal energy harvesting thermionic device. As shown, at time t=0 sec, a short duration heat addition is initiated lasting less than 500 seconds. The temperatures of the cathode and anode are raised from about room temperature (about 25° C.) to about 200° C. and 175° C., respectively, within 500 seconds. A Keithley multimeter (Model 2400) was used to measure current in milliamps, as reported in the graph (2200). The resulting current generated by the thermal energy harvesting thermionic device increased from an initial current (prior to the introduction of heat) about 0.2 milliamp to a maximum peak or spike of 0.2 milliamp (at about 400 seconds as shown in FIG. 22) before settling between 0.1 milliamp and 0.15 milliamp for a long duration of at least 1500 seconds before current measurements were ceased. Notably, even after the thermal gradient between the cathode and anode disappeared and the respective temperatures of cathode and the anode dropped below 150° C., the current production continued substantially unchanged for an extended period of time. A significance of the results set forth in the graph (2200) of FIG. 22 is that thermal perturbation of the thermal energy harvesting thermionic device, such as from the heating element (108) of FIG. 1, provides high power production for an extended period of time after the thermal perturbation is removed.

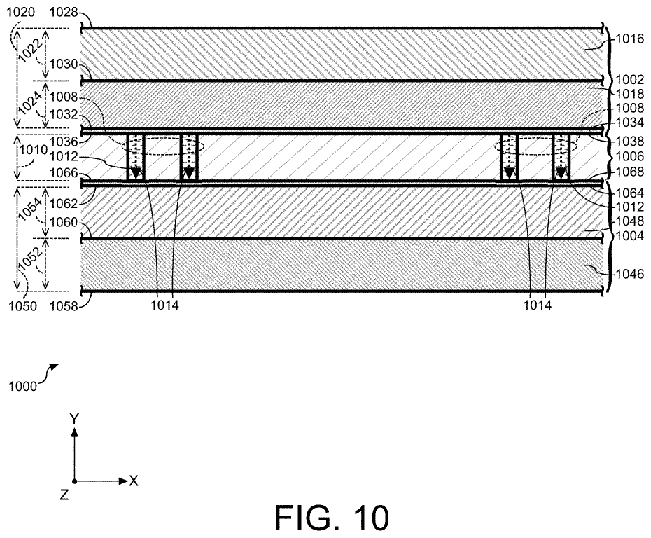

Recent improvements in thermionic power converters pertain to material selection based on work functions and corresponding work function values for the electrodes and using a fluid to fill the inter-electrode gap. Electron transfer density is limited by the materials of the electrodes and the materials of the fluid in the inter-electrode gap (i.e., the associated work functions). Representative and exemplary materials, features, conditions, etc. associated with thermal energy harvesting thermionic devices are described in further detail below in connection with FIGS. 10-21.

Temperature Sensor (112)

The apparatus of FIG. 1 is provided with one or more temperature sensors (112) to monitor the temperature of the thermal energy harvesting thermionic device (110). The temperature of any component of the thermal energy harvesting thermionic device (110) may be monitored. In an exemplary embodiment, the temperature of the cathode or a conductor contacting the cathode is measured. In another embodiment, the temperature of the anode or a conductor contacting the anode is measured. In still another embodiment, the temperatures of the cathode and the anode (or conductors contacting the same) are monitored for determining the temperature gradient. The temperature sensor (112) comprises one or more thermocouples according to an exemplary embodiment.

Controller (114)

The controller (114) of the apparatus (102) is operatively connected to the electrical energy storage device (106) and to the temperature sensor (112), as shown in FIG. 1. Although the controller (114) and the temperature sensor (112) are shown separately in FIG. 1, it should be understood that the controller (114) may be incorporated into the temperature sensor (112), or vice versa. When the temperature of the thermal energy harvesting thermionic device (110), in particular the nano-fluid (discussed below) as measured by the temperature sensor (112), falls below a temperature threshold, the controller (114) is notified by the temperature sensor (112). Alternatively, the controller (114) monitors the temperature sensor (112) for a temperature drop below the threshold temperature. In an embodiment, the temperature threshold is a temperature value. In another embodiment, the temperature threshold is a range of temperatures. The temperature threshold may be predetermined. For example, the temperature threshold may be any value between the freezing point and the boiling point of the nanofluid (discussed below) of the thermal energy harvesting thermionic device. In another embodiment, the temperature threshold is a temperature difference (temperature gradient) between the cathode and anode. In an exemplary embodiment, the system may be designed so that the operational elements are configurable in multiple dimensions, including but not limited to the nanofluid structure and composition and/or the selection and composition of the materials of the electrodes.

In response to the temperature of the thermal energy harvesting thermionic device (110) falling below the temperature threshold, the controller (114) activates the electrical energy storage device (106) to supply the electrical energy to the heating element (108). The heating element (108), in turn, thermally perturbs the thermal energy harvesting thermionic device (110). In an exemplary embodiment, the controller (114) activates the heating element (108) to generate a temperature in a range of about −200° C. to about 2,000° C. The temperature range is correlated with the composition of the nanofluid. For example, at −200 C the nanofluid composition may include an alkali metal, and at the highest temperature range the nanofluid composition may include molten salts. Similarly, in another embodiment, at room temperature, such as 25° C. to 200° C., the nanofluid composition may include organics, such as toluene, alkanes, alkane thiols, and/or water, with each composition having respective operational temperatures or temperature ranges. In an exemplary embodiment, the controller (114) activates the electrical energy storage device (106) for a period of about 4-10 seconds to about 100 seconds, which is sufficient time for the heating element (108) to generate heat for harvesting by the thermal energy harvesting thermionic device (110). The amount of time selected for activating the electrical energy storage device (106) may be based on various factors, including but not limited to the ambient temperature of the environment in which the device (110) is located, the temperature of the nano-fluid prior to activation, etc. The magnitude of the resulting current produced by the thermal energy harvesting thermionic device (110) will depend upon many factors, including the heat energy emitted by the heating element (108). In an exemplary embodiment, activating the heating element (108) for a limited duration, e.g. seconds, can increase the electrical output of the thermal energy harvesting thermionic device (110) for an extended duration, e.g. hours.

The controller (114), which may be embodied as a control circuit, may include at least one processor (e.g., a microprocessor), at least one microcontroller, at least one programmable logic device (e.g., field programmable gate arrays, programmable array logic, programmable logic devices), at least one application specific integrated circuit, or the like, or combinations including one or more thereof. The controller (114) may include or operatively communicate with a memory or memory module. Memory or memory modules may be in the form of nonvolatile data stores, such as hard drives and/or nonvolatile memory. A non-exhaustive list of more specific examples of memory includes the following: a portable computer diskette, a hard disk, a dynamic or static random access memory (RAM), a read-only memory (ROM), an erasable programmable read-only memory (EPROM or Flash memory), a magnetic storage device, a portable compact disc read-only memory (CD-ROM), a digital versatile disk (DVD), a memory stick, and any suitable combination of the foregoing. The memory may store one or more software-based control applications that include instructions that the control circuit executes to perform the functions described herein.

Re-Chargeable Power Storage Device (118)

The thermal energy harvesting thermionic device (110) is operatively connected to the rechargeable power storage device (118) through the charging circuit (116), which is discussed below. The output of a thermal energy harvesting thermionic device (100) is a DC voltage or current. In the embodiment of FIG. 1, the DC output is supplied to the rechargeable power storage device (118) to recharge (and optionally initially charge) the power storage device (118). In other embodiments described below, e.g., in connection with FIGS. 4 and 8, for example, the DC output may be supplied directly to an electrical load, such as a power-consumption device (120) (in addition or in the alternative to the rechargeable power storage device (118)).

Generally, rechargeable power storage devices can discharge electrical energy into a load, e.g., the power-consumption device (120), and be recharged in multiple cycles. In an exemplary embodiment, the rechargeable power storage device (118) comprises one or more rechargeable batteries. Non-limiting examples of rechargeable batteries include lithium ion, lithium-ion polymer, lead-acid, nickel-cadmium, and nickel-metal hydride batteries. In another embodiment, the rechargeable power storage device (118) comprises one or more secondary cells.

Charging Circuit (116)

In FIG. 1, the charging circuit (116) controls the flow of charging electrical energy from the thermal energy harvesting thermionic device (110) to the rechargeable power storage device (118), for example, to provide for electrical energy flow only when the power storage device (118) is in need of recharging.

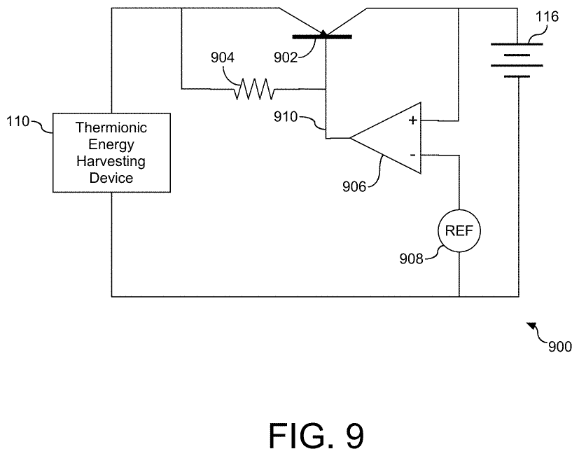

FIG. 9 is a diagram of a charging circuit (900) according to an exemplary embodiment that may be used as the charging circuit (116) of the embodiment of FIG. 1 for controlling the charging of the rechargeable power storage device (118) by the thermal energy harvesting thermionic device (110). Although the charging circuit (900) is described herein in conjunction with the apparatus (100) of FIG. 1, it should be understood that the charging circuit may be used in association with other apparatus discussed below, including but not necessarily limited to apparatus (200), (300), (500), (600), and (700) of FIGS. 2, 3, 5, 6, and 7, respectively.

The charging circuit (900) of FIG. 9 includes a series pass element (902), a resistor (904), a comparator (906), and a reference voltage (908). The charging circuit (900) is shown as part of the apparatus (102) of FIG. 1, in that the charging circuit (900) is operatively coupled to the thermal energy harvesting thermionic device (110) and the rechargeable power storage device (118).

The thermal energy harvesting thermionic device (110) functions as a power source in FIG. 9. When the thermal energy harvesting thermionic device (110) is connected to the charging circuit (900), the output of the comparator (906) is low if the voltage of the rechargeable power storage device (118) is below the reference voltage (908). The reference voltage is typically set at a termination voltage of the rechargeable power storage device (118). As known in the art, a battery charged beyond its termination voltage, also known as an overvoltage condition, can compromise the reliability of the battery cells. For example, in the case of single-cell lithium batteries, the termination voltage may be 4.1 to 4.2 volts, although these values should not be considered limiting. Low output from the power storage device (118) enables the comparator (906) to switch on the pass element (902). In the illustrated embodiment, the pass element (902) is illustrated as a bipolar junction transistor, which is provided by way of example. It should be understood that other mechanisms may be used as the pass element (902). Once the pass element (902) is switched on, the current flows from the thermal energy harvesting thermionic device (110) to the rechargeable power storage device (118). When the rechargeable power storage device (118) has been charged to a voltage that exceeds (or equals) the reference voltage (908), the comparator (906) switches off the pass element (902). The resistor (904) ensures that the pass element (902) switches off. In a non-limiting embodiment, the resistor (904) is a pull-up resistor,

The charging circuit (900) of FIG. 9 is an example of a charging circuit that may be used with embodiments described herein. Charging circuits are well known, and hence other charging circuits may be incorporated into the various embodiments described herein. It is within the scope of this disclosure to incorporate charging circuits having special charging capabilities, such as pulse charging or trickle charging. Examples of trickle charging circuits are disclosed in U.S. Pat. No. 6,492,792.

Power-Consumption Device (120)

The power-consumption device (120), also referred to herein as an electrical load, may be selected from a wide array of consumer and commercial products and goods, including, by way of example and not limitation, mobile telephones, cordless telephones, consumer electronics, portable electronics, computers such as laptop computers and tablet computers, personal digital assistants (PDAs), portable radios, power tools, watches, calculators, game systems and controllers, cameras, video recorders, portable televisions, global positioning systems (GPS), data transfer devices, lighting goods and systems, home products, toys, headphones, DVD and CD players, MP3 players, voice recorders, sensors, controllers, grooming instruments, alarm systems, weapons such as stun guns, backup power sources, military equipment, emergency equipment, utility equipment, vehicle controls and systems, appliances, telecommunications, etc.

In an exemplary embodiment, the power-consumption device (120) includes an integrated circuit and memory. FIGS. 1-8 illustrate the power-consumption devices (120), (220), (320), (420), (520), (620), (720), and (820) as external to the respective apparatus (102), (202), (302), (402), (502), (602), (702), and (802), respectively. In alternative embodiments, apparatus (102), (202), (302), (402), (502), (602), (702), and (802) may be incorporated into the power-consumption devices (120), (220), (320), (420), (520), (620), (720), and (820), respectively. The apparatus (102), (202), (302), (402), (502), (602), (702), and (802) disclosed herein are also contemplated for use by retrofitting or redesigning power-consumption devices (120), (220), (320), (420), (520), (620), (720), and (820), respectively.

Housing (104)

In an exemplary embodiment, the housing (104) encloses the electrical energy storage device (106), the heating element (108), the thermal energy harvesting thermionic device (110), the temperature sensor (112), the controller (114), the charging circuit (116), and the rechargeable power storage device (118). In another embodiment, the housing partially encloses the electrical energy storage device (106), the heating element (108), the thermal energy harvesting thermionic device (110), the temperature sensor (112), the controller (114), the charging circuit (116), and the rechargeable power storage device (118). In still another embodiment, the housing (104) encloses one or more of the electrical energy storage device (106), the heating element (108), the thermal energy harvesting thermionic device (110), the temperature sensor (112), the controller (114), the charging circuit (116), and the rechargeable power storage device (118), and partially encloses the other components. One or more components (106), (108), (110), (112), (114), (116), and/or (118) of the apparatus (102) may be externally situated outside the housing (104).

According to an exemplary embodiment, the housing (104) is made of an aerogel material. However, the housing (104) may be made of other materials, whether conductive, semi-conductive, or insulating. Representative materials include metals, alloys, plastics, glass, etc.

### Alternative Embodiments and Configurations (FIGS. 2-8)

FIG. 2 illustrates a modification to the embodiment of FIG. 1. FIG. 2 depicts a block diagram (200) that includes an apparatus (202), a housing (204), an electrical energy storage device (206), e.g., capacitor, a heating element (208), a thermal energy harvesting thermionic device (210), a temperature sensor (212), controller (214), a charging circuit (216), a rechargeable power storage device (218), and a power-consumption device (220) having the same or similar properties and features of corresponding apparatus and components (102), (104), (106), (108), (110), (112), (114), (116), (118), and (120), respectively. In the interest of brevity, the description of components, properties, features, etc. associated with FIG. 1 is incorporated herein by reference with respect to FIG. 2. The principal difference between the block diagrams (100) and (200) of FIGS. 1 and 2, respectively, is that the rechargeable power storage device (218) is positioned internal to the power-consumption device (220) in FIG. 2, whereas the rechargeable power storage device (118) is positioned internal to the apparatus (102) in FIG. 1.

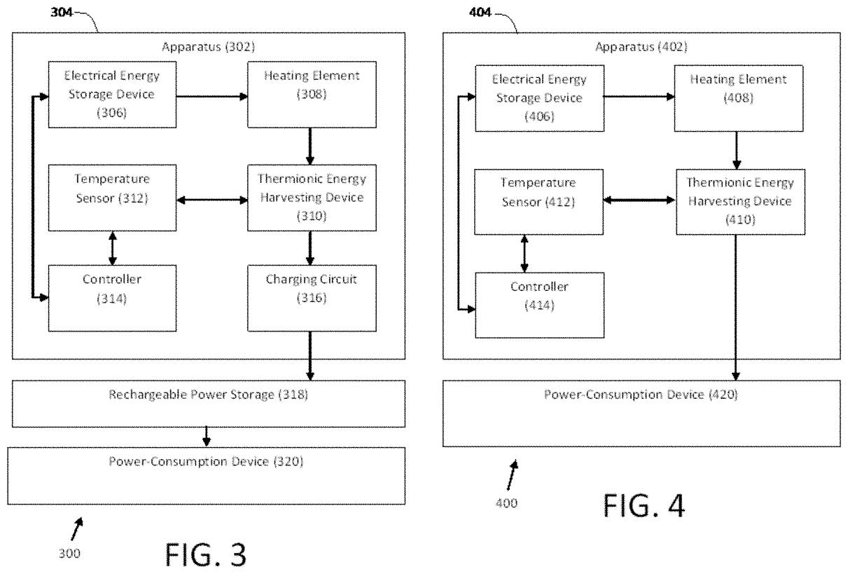

FIG. 3 depicts another modification to the embodiment of FIG. 1. FIG. 3 illustrates a block diagram (300) that includes an apparatus (302), a housing (304), an electrical energy storage device (306), e.g., a capacitor, a heating element (308), a thermal energy harvesting thermionic device (310), a temperature sensor (312), a controller (314), a charging circuit (316), a rechargeable power storage device (318), and a power-consumption device (320) having the same or similar properties and features of corresponding apparatus and components (102), (104), (106), (108), (110), (112), (114), (116), (118), and (120), respectively. In the interest of brevity, the description of components, properties, features, etc. associated with FIG. 1 is incorporated herein by reference with respect to FIG. 3. The principal difference between the block diagrams (100) and (300) of FIGS. 1 and 3, respectively, is that the rechargeable power storage device (318) is positioned external to the apparatus (302) and the power-consumption device (320) in FIG. 3, whereas the rechargeable power storage device (118) is positioned internal to the apparatus (102) in FIG. 1.

FIG. 4 depicts another modification to the embodiment of FIG. 1. FIG. 4 illustrates a block diagram (400) that includes an apparatus (402), a housing (404), an electrical energy storage device (406), e.g., a capacitor, a heating element (408), a thermal energy harvesting thermionic device (410), a temperature sensor (412), a controller (414), and a power-consumption device (420) having the same or similar properties and features of corresponding apparatus and components (102), (104), (106), (108), (110), (112), (114), and (120), respectively. In the interest of brevity, the description of components, properties, features, etc. associated with FIG. 1 is incorporated herein by reference with respect to FIG. 4. The principal difference between the block diagrams (100) and (400) of FIGS. 1 and 4, respectively, is that the block diagram (400) of FIG. 4 does not include a charging circuit or a rechargeable power storage device, whereas the block diagram (100) of FIG. 1 includes the charging circuit (116) and the rechargeable power storage device (118) positioned internal to the apparatus (102). In the embodiment of FIG. 4, electricity generated by the thermal energy harvesting thermionic device (410) is used to directly power the electrical load, i.e., the power-consumption device (420).

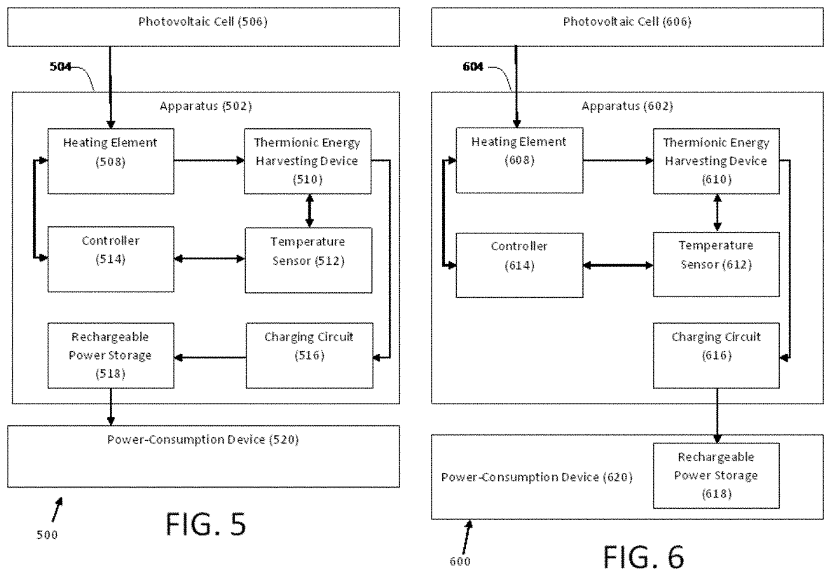

Referring now more particularly to FIG. 5, a block diagram (500) depicts an apparatus (502) for providing power to a power-consumption device (520). The apparatus (502) includes a housing (504) containing a heating element (508), a thermal energy harvesting thermionic device (510), a temperature sensor (512), a controller (514), a charging circuit (516), and a rechargeable power storage device (518). The apparatus (502) is operatively associated with a photovoltaic cell (506), which is illustrated positioned external to, e.g., mounted on, the housing (504). The photovoltaic cell (506) converts light energy to electrical energy. The heating element (508) is operatively connected to the photovoltaic cell (506) to convert electrical energy supplied by the photovoltaic cell (506) to heat. The thermal energy harvesting thermionic device (510) is positioned proximal to the heating element (508) to receive the heat from the heating element (508) and generate an electrical output. The thermal energy harvesting thermionic device (510) includes at least a cathode, an anode spaced from the cathode to provide an inter-electrode gap between the cathode and the anode, and a plurality of nanoparticles suspended in a fluid medium contained in the inter-electrode gap. The nanoparticles are arranged in the inter-electrode gap to permit ion transfer between the cathode and the anode. The temperature sensor is configured to monitor the temperature of the thermal energy harvesting thermionic device. The controller (514) is operatively connected to the photovoltaic cell (506) and the temperature sensor (512) to activate the photovoltaic cell (506) to supply the electrical energy to the heating element (508) in response to the temperature of the thermal energy harvesting thermionic device (510) falling below the temperature threshold.

In an exemplary embodiment, the housing (504) encloses the heating element (508), the thermal energy harvesting thermionic device (510), the temperature sensor (512), the controller (514), the charging circuit (516), and the rechargeable power storage device (518). In another embodiment, the housing (504) partially encloses the heating element (508), the thermal energy harvesting thermionic device (510), the temperature sensor (512), the controller (514), the charging circuit (516), and the rechargeable power storage device (518). In still another embodiment, the housing (504) encloses one or more of the heating element (508), the thermal energy harvesting thermionic device (510), the temperature sensor (512), the controller (514), the charging circuit (516), and the rechargeable power storage device (518), and partially encloses the other components.

In the interest of brevity, the description of components, properties, features, etc. associated with FIG. 1 is incorporated herein by reference with respect to FIG. 5 and FIGS. 6-8, discussed below. The principal difference between the block diagrams (100) and (500) of FIGS. 1 and 5, respectively, is that the electrical energy storage device (106) positioned internal to the housing (104) of FIG. 1 is replaced by the photovoltaic cell (506), which in an exemplary embodiment is positioned exterior to the housing (504).

FIG. 6 illustrates a modification to the embodiment of FIG. 5. FIG. 6 depicts a block diagram (600) that includes an apparatus (602), a housing (604), a photovoltaic cell (606), a heating element (608), a thermal energy harvesting thermionic device (610), a temperature sensor (612), a controller (614), a charging circuit (616), a rechargeable power storage device (618), and a power-consumption device (620) having the same or similar properties and features of corresponding apparatus and components (502), (504), (506), (508), (510), (512), (514), (516), (518), and (520), respectively. In the interest of brevity, the description of components, properties, features, etc. associated with FIG. 5 is incorporated herein by reference with respect to FIG. 6. The principal difference between the block diagrams (500) and (600) of FIGS. 5 and 6, respectively, is that the rechargeable power storage device (618) is positioned internal to the power-consumption device (620) in FIG. 6, whereas the rechargeable power storage device (518) is positioned internal to the apparatus (502) in FIG. 5.

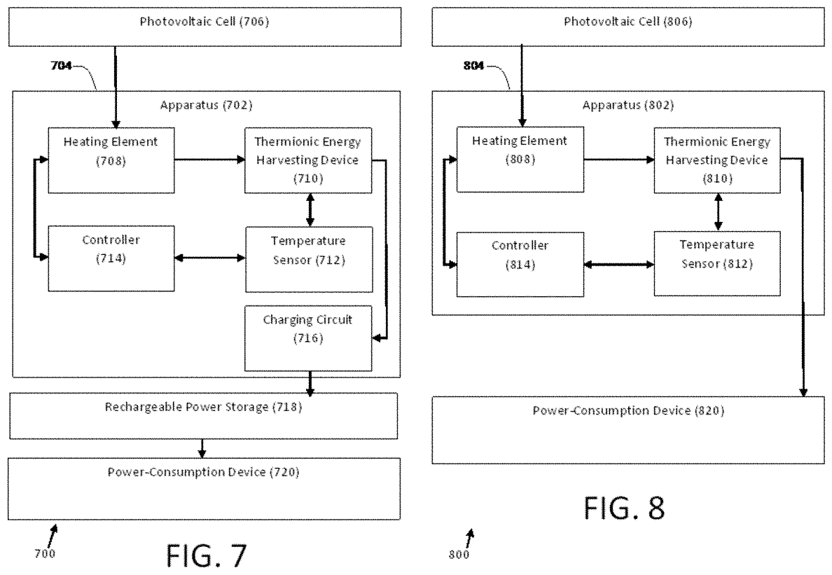

FIG. 7 depicts another modification to the embodiment of FIG. 5. FIG. 7 illustrates a block diagram (700) that includes an apparatus (702), a housing (704), a photovoltaic cell (706), a heating element (708), a thermal energy harvesting thermionic device (710), a temperature sensor (712), a controller (714), a charging circuit (716), a rechargeable power storage device (718), and a power-consumption device (720) having the same or similar properties and features of corresponding apparatus and components (502), (504), (506), (508), (510), (512), (514), (516), (518), and (520), respectively. In the interest of brevity, the description of components, properties, features, etc. associated with FIG. 5 is incorporated herein by reference with respect to FIG. 7. The principal difference between the block diagrams (500) and (700) of FIGS. 5 and 7, respectively, is that the rechargeable power storage device (718) is positioned external to the apparatus (702) and the power-consumption device (720) in FIG. 7, whereas the rechargeable power storage device (518) is positioned internal to the apparatus (502) in FIG. 5.

FIG. 8 depicts another modification to the embodiment of FIG. 5. FIG. 8 illustrates a block diagram (800) that includes an apparatus (802), a housing (804), a photovoltaic cell (806), a heating element (808), a thermal energy harvesting thermionic device (810), a temperature sensor (812), a controller (814), and a power-consumption device (820) having the same properties and features of corresponding apparatus and components (502), (504), (506), (508), (510), (512), (514), (516), and (518), respectively. In the interest of brevity, the description of components, properties, features, etc. associated with FIG. 5 is incorporated herein by reference with respect to FIG. 8. The principal difference between the block diagrams (500) and (800) of FIGS. 5 and 8, respectively, is that the block diagram (800) of FIG. 8 does not include a charging circuit or a rechargeable power storage device, whereas the block diagram (500) of FIG. 5 includes the charging circuit (516) and the rechargeable power storage device (518) positioned internal to the apparatus (502). In the embodiment of FIG. 8, electrical energy generated by the thermal energy harvesting thermionic device (810) is used to directly power an electrical load, i.e., the power-consumption device (820).

The embodiments disclosed in FIGS. 1-8 may be combined with one another and modified to include features of one another. For example, the electrical energy storage device (106), (206), (306), and/or (406) of any of FIGS. 1 to 4 can be incorporated into the apparatus (502), (602), (702), and/or (802) of any of FIGS. 5 to 8. Likewise, the photovoltaic cell (506), (606), (706), and/or (806) of any of FIGS. 5 to 8 can be associated with into the apparatus (102), (202), (302) and/or (402) of FIGS. 1-4. For example, the photovoltaic cell (506), (606), (706), and/or (806) can be used to charge the electrical energy storage device (106), (206), (306), and/or (406). As another example, the re-chargeable power storage devices (118), (218), (318), (518), (618), and/or (718) may be provided both in the apparatus housing (104), (204), (304), (404), (504), (604), (704), and/or (804) and in the power-consumption device (120), (220), (320), (420), (520), (620), (720), and/or (820). The thermal energy harvesting thermionic device (110), (210), (310), (410), (510), (610), (710), and/or (810) of FIGS. 1 to 8 may be used to charge or re-charge the re-chargeable power storage device (118), (218), (318), (518), (618), and/or (718) and directly power the power-consumption device (120), (220), (320), (420), (520), (620), (720), and/or (820).

Embodiments of the thermal energy harvesting thermionic devices (110), (210), (310), (410), (510), (610), (710), and/or (810) will now be described in greater detail with reference to FIGS. 10-20. Reference is now made to FIG. 10 illustrating a sectional view of an embodiment of a thermal energy harvesting thermionic device (1000) that is configured to convert heat into electrical power, i.e., electricity. In exemplary embodiments, the device (1000) may be nano-scale and/or contain one or more nano-scale components. Each of the dimensions, including a thickness dimension defined parallel to a first-axis, also referred to herein as a vertical axis, i.e., Y-axis in FIG. 10, a longitudinal dimension parallel to a second-axis, i.e., X-axis in FIG. 10, also referred to herein as a horizontal axis, and a lateral dimension parallel to a third axis-axis, i.e. Z-axis in FIG. 10, orthogonal to the X-axis and Y-axis, are shown for reference. The X-axis, Y-axis, and Z-axis are orthogonal to each other in physical space.

The thermal energy harvesting thermionic device (1000) is sometimes referred to herein as a cell. In exemplary embodiments, the thermal energy harvesting thermionic device (1000) is illustrated as a sheet or a plurality of adjacently positioned sheets or layers, e.g., that are stacked or wound. A plurality of devices (1000) may be organized as a plurality of cells, or a plurality of layers, with the cells or layers arranged in series or parallel, or a combination of both to generate electrical power at the desired voltage, current, and power output.

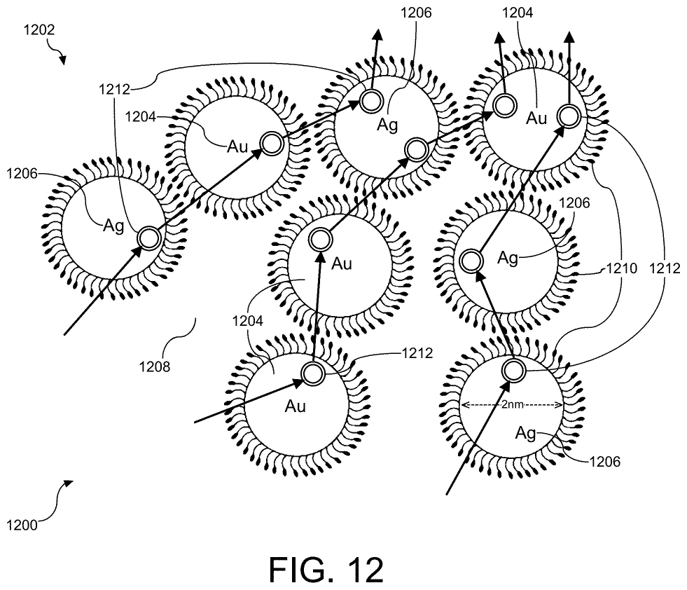

The thermal energy harvesting thermionic device (1000) includes an emitter electrode (also referred to herein as the cathode) (1002) and a collector electrode (also referred to herein as the anode) (1004) positioned to define an inter-electrode gap (or interstitial space) (1040) therebetween. In an embodiment, a spacer (1006) of separation material, sometimes referred to herein as a standoff or spacer, maintains separation between the electrodes (1002) and (1004). While the spacer (1006) is referred to herein in the singular, it should be understood that the spacer (1006) may comprise a plurality of elements. The spacer (1006) may be an insulator or comprise one or more materials that collectively exhibit non-conductive properties. The spacer (1006) is illustrated in direct contact with the electrodes (1002) and (1004). The electrodes (1002) and (1004) and the spacer (1006) define a plurality of closed apertures (1008), also referred to herein as cavities, in the inter-electrode gap (1040). The apertures (1008) extend in the Y direction between the electrodes (1002) and (1004) for a distance (1010) in the range, for example, of about 1 nanometer (nm) to about 100 nm, or in the range, for example, of about 1 nm to about 20 nm. A fluid (1012), also referred to as a nano-fluid (discussed further herein with reference to FIG. 12), is received and maintained within each aperture (1008).

In alternative embodiments, no spacer (1006) is used and only the nano-fluid (1012) is positioned between the electrodes (1002) and (1004). Accordingly, the thermal energy harvesting thermionic device (1000) includes two opposing electrodes (1002) and (1004), optionally separated by the spacer (1006) with a plurality of apertures (1008) extending between the electrodes (1002) and (1004) and configured to receive the nano-fluid (1012).

The emitter electrode (1002) and the collector electrode (1004) each may be fabricated from different materials, with the different materials having separate and different work function values. The work function of a material or a combination of materials is the minimum thermodynamic work, i.e., minimum energy, needed to remove an electron from a solid to a point in a vacuum immediately outside a solid surface of the material. The work function is a material-dependent characteristic. Work function values are typically expressed in units of electron volts (eV). Accordingly, the work function of a material determines the minimum energy required for electrons to escape the surface, with lower work functions generally facilitating electron emission.

The difference in work function values between the electrodes (1002) and (1004) due to the different electrode materials influences the voltage that can be achieved. Thus, to generate high power, the difference in work function values between the electrodes (1002) and (1004) is large in an exemplary embodiment. In an embodiment, the work function value of the collector electrode (1004) is smaller than the work function value of the emitter electrode (1002). The different work function values induces a contact potential difference between the electrodes (1002) and (1004) that has to be overcome, e.g., by the application of heat to the emitter electrode (1002), to transmit electrons through the fluid (1012) within the apertures (1008) from the emitter electrode (1002) to the collector electrode (1004). The total of the work function value of the collector electrode (1004) and the contact potential difference is less than or equal to the work function of the emitter electrode (1002) in an exemplary embodiment. Maximum flow occurs when the total of the work function value of the collector electrode (1004) and the contact potential equals the work function of the emitter electrode (1002).

Both electrodes (1002) and (1004) emit electrons; however, as explained in more detail elsewhere herein, once the contact potential difference is overcome, the emitter electrode (1002) will emit significantly more electrons than the collector electrode (1004), which is influenced by an electric field that suppresses electron production from the collector electrode (1004). A net flow of electrons will be transferred from the emitter electrode (1002) to the collector electrode (1004), and a net electron current (1014) will flow from the emitter electrode (1002) to the collector electrode (1004) through the apertures (1008). This net electron current (1014) causes the emitter electrode (1002) to become positively charged and the collector electrode (1004) to become negatively charged. Accordingly, the thermal energy harvesting thermionic device (1000) generates an electron current (1014) that is transmitted from the emitter electrode (1002) to the collector electrode (1004).

The emitter electrode (1002) may be manufactured with a first backing (1016), which may comprise, for example, a polyester film, e.g., Mylar®, and a first layer (1018) extending beneath the first backing (1016). The first layer (1018) may be comprised of graphene, platinum (Pt), or other suitable materials. In an embodiment, the emitter electrode (1002) has an emitter electrode thickness measurement (1020) extending in the Y direction that is, for example, approximately 0.25 millimeters (mm), such measurement being non-limiting, or in a range of, for example, about 2 nm to about 0.25 mm, such measurements being non-limiting. The first backing (1016) is shown in FIG. 10 with a first backing thickness measurement (1022), and the first layer (1018) is shown herein with a first layer thickness measurement (1024), each extending in the Y direction. In an embodiment, the first backing thickness measurement (1022) and the first layer thickness measurement (1024) range of, for example, about 0.01 mm to about 0.125 mm, or, for example, 0.125 mm, such values being non-limiting. The first backing measurement (1022) and the first layer measurement (1024) may have the same or different measurement values.

In an exemplary embodiment, prior to assembly, the first layer (1018) is sprayed onto the first backing (1016) so as to embody the first layer (1018) as a nanoparticle layer that is approximately 2 nm (i.e., the approximate length of a nanoparticle), where the 2 nm value should be considered non-limiting. In an embodiment, the thickness (1024) of the first layer (1018) may be in a range of, for example, about 1 nm to about 20 nm. In another embodiment, the thickness (1024) of the first layer (1018) may be in a range of, for example, 0.01 mm to 0.125 mm. Generally, smaller thicknesses have higher energy densities and less wasted energy. The first backing (1016) has a first outer surface (1028). The first backing (1016) and the first layer (or the nanoparticle layer) (1018) define a first interface (1030) therebetween. The first layer (or the nanoparticle layer) (1018) defines a first surface (1032) facing the inter-electrode gap (1040). Alternatively to spraying, the first layer (1018) may be pre-formed and applied to the first backing layer (1016).

A first coating (1034), such as cesium oxide (Cs₂O), at least partially covers the first surface (1032) to form an emitter surface (1036) of the first electrode (1002) that directly interfaces with a first spacer surface (1038). Accordingly, the emitter electrode (1002) of the embodiment illustrated in FIG. 10 includes a first layer (or nanoparticle layer) (1018) adjacent to the first backing (1016) and the first coating (1034) below the first surface (1032).

In FIG. 10, the collector electrode (1004) includes a second backing (1046), which may be comprised of a polyester film, and at least one second layer (1048), which may be comprised of, for example, graphene or aluminum (Al), extending over the second backing (1046). The collector electrode (1004) has a collector electrode thickness measurement (1050) extending in the Y direction that is, for example, approximately 0.25 millimeters (mm), such measurement being non-limiting, or in a range of, for example, about 2 nm to about 0.25 mm, such values being non-limiting. For example, in an embodiment, a second backing measurement (1052) of the second backing (1046) and a second layer measurement (1054) of the layer (1048) are each approximately 0.125 mm, such values being non-limiting. In an embodiment, the second backing measurement (1052) and the second layer measurement (1054) may range from, for example, about 0.01 mm to about 0.125 mm, or each approximately 0.125 mm, such values being non-limiting. The second backing measurement (1052) and the second layer measurement (1054) may have the same or different measurement values.

In an embodiment, the second layer (1048) is sprayed on to the second backing (1046) to embody the second layer (1048) as a second nanoparticle layer that is approximately 2 nm thick, where the 2 nm value should be considered non-limiting. The second layer measurement (1054) of the second layer (1048) may range from, for example, approximately 1 nm to about 20 nm. In another embodiment, the second layer measurement (1054) of the second layer (1048) may be in a range of, for example, 0.01 mm to 0.125 mm. As discussed above in connection with the first layer (1018), generally, smaller thicknesses have higher energy densities and less wasted energy. The second backing (1046) has a second outer surface (1058). The second backing (1046) and the second layer/nanoparticle layer (1048) define a second interface (1060). The second layer (or the second nanoparticle layer) (1048) defines a second surface (1062) facing the inter-electrode gap (1040). Alternatively to spraying, the second layer (1048) may be pre-formed and applied to the second backing (1046).

A second coating (1064), which may be comprised of cesium oxide (Cs₂O), at least partially covers the second surface (1062) to form a collector surface (1066) of the collector electrode (1004) that directly interfaces with a second surface (1068) of the spacer (1006). Accordingly, the collector electrode (1004) of FIG. 10 includes the second layer/nanoparticle layer (1048) on the second backing (1046) and the Cs₂O coating (1064) on the second surface (1062).

The first coating (1034) and the second coating (1064) are formed on the first and second surfaces (1032) and (1062), respectively. In an embodiment, an electrospray or a nano-fabrication technique is employed to form or apply the first and second coatings (1034) and (1064), respectively. The first and second coatings (1034) and (1064) can be applied in one or more predetermined patterns that may be the same as or different from one another.

In exemplary embodiments, a percentage of coverage of each of the first surface (1032) and second surface (1062) with the respective (Cs₂O) coating layers (1034) and (1064) is within a range of at least 50%, and up to 70%, and in at least one embodiment is about 60%. The Cs₂O coatings (1034) and (1064) reduce the work function values of the electrodes (1002) and (1004) from the work function values of platinum (Pt), which is an embodiment is 5.65 electron volts (eV), and aluminum (Al), which in an embodiment is 4.28 eV. The emitter electrode (1002) with the Cs₂O coating layer has a work function value ranging from about 0.5 to about 2.0 eV, and in an embodiment is approximately 1.5 eV, and the collector electrode (1004) with the Cs₂O coating layer has a work function value of about 0.5 to about 2.0 eV, and in an embodiment is approximately 1.5 eV. In an embodiment, the electrodes (1002) and (1004) are comprised of graphene, and are referred to herein as graphene electrodes (1002) and (1004). The graphene electrodes (1002) and (1004) can exhibit work function values below 1.0 eV when coated with cesium oxide, gold, tungsten, and other elements and compounds. Sulfur may be incorporated into the coatings (1034) and (1064) to improve the bonding of the coating to the graphene electrodes (1002) and (1004), particularly where the electrodes are graphene and the sulfur creates covalent bonding between the electrodes (1002) and (1004) and their respective coatings (1034) and (1064). The respective work function values of the electrodes (1002) and (1004) can be made to differ, even when both are comprised of graphene, by incorporating different coatings (1034) and (1064) into the electrodes (1002) and (1004). Suitable graphene electrodes are available through ACS (Advanced Chemical Suppliers) Materials, and include Trivial Transfer Graphene™ (TTG 10055).

In an embodiment, the surface area coverage on the emitter electrode (1002) or the collector electrode (1004) with Cs₂O is spatially resolved, e.g., applied in a pattern or non-uniform across the length of the corresponding surface, and provides a reduction in a corresponding work function to a minimum value. In an exemplary embodiment, the work function value, from a maximum of about 2.0 eV is reduced approximately 60-80% corresponding to the surface coverage of the Cs₂O, e.g. cesium oxide. Accordingly, the lower work function values of the electrodes (1002) and (1004) improve operation of the thermal energy harvesting thermionic device (1000) as described herein.

Platinum (Pt)-coated on copper foil and aluminum (Al) materials optionally are selected for the first and second electrodes (1002) and (1004), respectively, due to at least some of their metallic properties, e.g., strength and resistance to corrosion, and the measured change in work function values when the thermionic emissive material of Cs₂O is layered thereon. Alternative materials may be used, such as graphene, noble metals including, and without limitation, rhenium (Re), osmium (Os), ruthenium (Ru), iridium (Ir), rhodium (Rh), and palladium (Pd), or any combination of these metals. In addition, and without limitation, non-noble metals such as gold (Au), tungsten (W), tantalum (Ta), and molybdenum (Mo), and combinations thereof, may also be used. For example, and without limitation, tungsten (W) nanoparticles may be used rather than platinum (Pt) nanoparticles to form the first surface (1032), and gold (Au) nanoparticles may be used rather than aluminum (Al) nanoparticles to form the second surface (1062). Accordingly, the selection of the materials to use to form the nanoparticle surfaces (1032) and (1062) can be principally based on the work functions of the electrodes (1002) and (1004), and more specifically, the difference in the work functions once the electrodes (1002) and (1004) are fully fabricated.

The selection of the first and second coatings (1034) and (1064), e.g., thermionic electron emissive material, on the first surface (1032) and second surface (1062), respectively, may be partially based on the desired work function value of the electrodes (1002) and (1004), respectively, and chemical compatibility between the deposited materials, and the deposited thermionic electron emissive materials of the first and second coatings (1034) and (1064), respectively. Deposition materials include, but are not limited to, thorium, aluminum, cerium, and scandium, as well as oxides of alkali or alkaline earth metals, such as cesium, barium, calcium, and strontium, as well as combinations thereof and combinations with other materials. In at least one embodiment, the thickness of the layer of patterned thermionic electron emissive material of the first and second coatings (1034) and (1064) is approximately 2 nm, where the 2 nm value should be considered non-limiting. Accordingly, the electrodes (1002) and (1004) have highly desirable work functions.

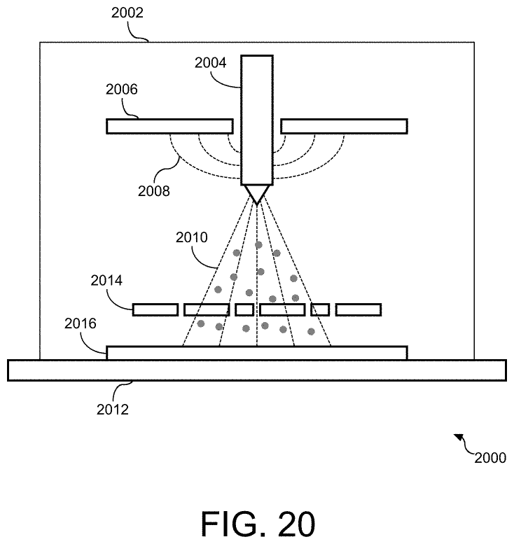

Exemplary electrospray and nano-fabrication technique(s) and associated equipment, including three-dimensional printing and four-dimensional printing (in which the fourth dimension is varying the nanoscale composition during printing to tailor properties) for forming the first layer/first nanoparticle layer (1018), the second layer/second nanoparticle layer (1048), the spacer (1006) and other layers and coatings discussed herein, including those of the device (1000), are set forth in U.S. Application Publication No. 2015/0251213. Generally, that application discloses a composition including a nano-structural material, grain growth inhibitor nanoparticles, and at least one of a tailoring solute or tailoring nanoparticles. Grain growth inhibitors are preferably not used in the embodiments described herein. A simplified diagram of an electrospray apparatus or system is generally designated by reference numeral (2000) in FIG. 20. The electrospray system (2000) includes an outer housing (2002) that may be embodied as a vented heat shield containing a Faraday cage (not shown). Within the outer housing (2002), an emitter tube (also referred to as an electrospray nozzle) (2004) coupled to the bottom of a material reservoir (not shown) receives molten material from the material reservoir through a capillary tube (not shown). An extractor electrode (2006) is configured for generating an electric field (2008) to extract the molten material from the electrospray nozzle (2004) to form a stream or spray (2013) of droplets of nanoparticle size. The electric field (2008) also drives the spray of droplets (2010) towards a moving stage (2012) that is movable relative to the extractor electrode (2006). The extractor electrode (2006) can also generate a magnetic field for limiting dispersion of the stream (2010) of droplets. In an exemplary embodiment, the extractor electrode (2006) has a toroid shape, with the electrospray nozzle (2004) extending through the center of the toroid. FIG. 20 shows the use of a template (2014) for forming a predetermined pattern on a substrate (2016). For example, the substrate (2016) can be the first layer (1018) of the emitter electrode (1002) or the second layer (1048) of the collector electrode (1006) of FIG. 10, and the template (2014) can be used to control the deposition of the (cesium oxide) coating (1034) or (1064).

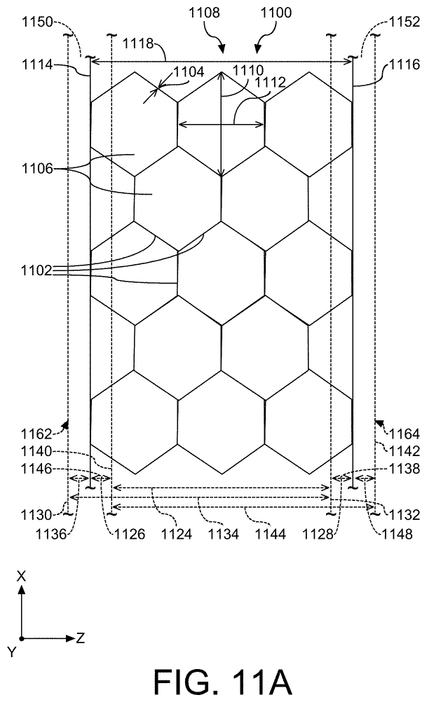

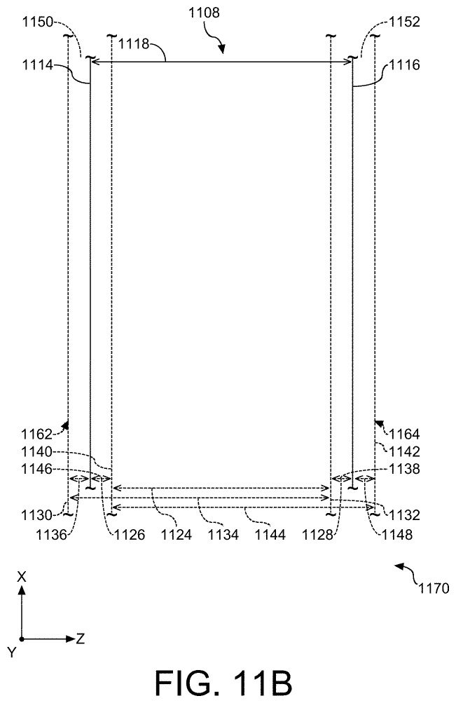

FIG. 11A depicts a top view of an embodiment of a spacer (1100) in relationship to the adjacent electrodes (1162) and (1164), for use in a thermal energy harvesting thermionic device, such as the device (1000) as shown and described in reference to FIG. 10. The spacer (1100) and the electrodes (1162) and (1164) are not shown to scale.

The spacer (1100) includes a plurality of interconnected edges (1102). The edges (1102) have a thickness or edge measurement (1104) in the range of, for example, about 2.0 nm to about 0.25 mm. In the illustrated embodiment, the interconnected edges (1102) collectively define a plurality of hexagonal apertures, also referred to herein as cavities (1106), in a honeycomb array (1108). The cavities (1106) extend in a direction parallel to the Y-axis. The spacer (1100) may be configured as a uniform or relatively uniform layer, e.g., contiguous and with or without limited apertures. The apertures or cavities, either uniformly or non-uniformly provided across the width and/or length of the spacer material, may be in a range of, for example, greater than 0 mm to about 0.25 mm in the Y-axis direction.

Referring to FIG. 11B, a top view of another embodiment of a spacer (1170) and the adjacent electrodes (1162) and (1164), is shown for use in a thermal energy harvesting thermionic device, such as the device (1000) as shown and described in FIG. 10. The embodiments shown and described in FIGS. 11A and 11B are provided with the same reference numerals, where appropriate, to designate identical or like parts. The spacer (1170) may be comprised of a permeable or semi-permeable material, which in an embodiment may be adapted to receive or be coated or impregnated with the nano-fluid.

Referring to FIG. 11A, the apertures (1106) have a first dimension (1110) and a second dimension (1112) each having a value in a range between, for example, 2.0 nm and 100 microns. In an embodiment, the edges (1102), the apertures (1106), and the array (1108) form various shapes, configurations, and sizes, including the dimensions and sizing of the apertures (11106), that enable operation of spacer (1100) as described herein, including, without limitation, circular, rectangular, and elliptical apertures (1106).

The spacers (1100) and (1170), shown in FIGS. 11A and 11B, respectively, include a first outer edge (1114) and a second outer edge (1116) that define the Z-dimensions of the spacer (1100), (1170). The spacer (1100), (1170) has a distance measurement (1118) in the lateral dimension (Z) between the lateral side edges (1114) and (1116) in a range of, for example, about 1 nm to about 10 microns.

As shown in FIGS. 11A and 11B, the electrodes (1162) and (1164) are offset in the lateral dimension Z with respect to one another and to the spacer (1100), (1170). Specifically, the emitter electrode (1162) includes opposite first and second lateral side edges (1130) and (1132) separated by a first distance (1134), and the collector electrode (1164) includes opposite third and fourth lateral side edges (1140) and (1142) separated by a second distance (1144). The values of the first and second distances (1134) and (1144) may be the same or different from one another, and may be within a range of, for example, approximately 10 mm to approximately 2.0 m.

With respect to the first electrode (1162), the first lateral side edge (1130) extends in the lateral direction Z beyond the first lateral support side edge (1114) of the spacer (1100), (1170) by a third distance (1136), and the second lateral support side edge (1116) of the spacer (1100), (1170) extends in the lateral direction Z beyond the second lateral side edge (1132) by a fourth distance (1128).

With respect to the second electrode (1164), the first lateral support side edge (1114) of the spacer (1100), (1170) extends in the lateral direction Z beyond the third lateral side edge (1140) by a fifth distance (1126), and the fourth lateral side edge (1142) extends in the lateral direction Z beyond the second lateral support side edge (1116) of the spacer (1100), (1170) by a sixth distance (1148).

The third distance (1136), the fourth distance (1128), the fifth distance (1126), and the sixth distance (1148) may be the same or different from one another and within a range of, for example, approximately 1.1 nm to approximately 10 microns. The spacer (1100), (1170) may have a lateral measurement (1118) with respect to the Z-axis greater than lateral measurements (1134) and (1144) of the electrodes (1162) and (1164), respectively. The spacer measurements shown and described herein reduce a potential for electrodes, such as the electrodes (1002) and (1004), when the spacer is incorporated into the device (1000) of FIG. 10. The direct contacting of the electrodes (1002) and (1004) would create a short circuit.

Each of the lateral support side edges (1114) and (1116) may receive at least one layer of an electrically insulating sealant that electrically isolates the portions (1150) and (1152) of the electrodes (1162) and (1164), respectively, that extend beyond the lateral support side edges (1114) and (1116), respectively. Accordingly, each of the electrodes (1162) and (1164) may be offset from the spacer (1100), (1170) to reduce the potential for the electrodes (1162) and (1164) contacting each other and creating a short circuit.

In exemplary embodiments, the at least one spacer (1100) and/or (1170), also referred to herein as dielectric spacers, as shown and described in FIGS. 11A and 11B, respectively, are fabricated with a dielectric material, such as, and without limitation, silica (silicon dioxide), alumina (aluminum dioxide), titania (titanium dioxide), and boron-nitride. The apertures (1106) extend between the electrodes (1162) and (1164) for the distance (1010) (with reference to FIG. 10), e.g., in the Y-dimension, in a range from about 1 nanometer (nm) to about 10 microns. A fluid, e.g., the nano-fluid (1012) of FIG. 10, is received and maintained within each of the apertures (1106). The dielectric spacer (1100), (1170) is positioned between, and in direct contact with, the electrodes (1162) and (1164).

Referring to FIG. 12, a diagram (1200) is provided to illustrate a schematic view of an embodiment of a fluid (1202), also referred to herein as a nano-fluid. As shown, the nano-fluid (1202) includes a plurality of gold (Au) nanoparticle clusters (1204) and a plurality of silver (Ag) nanoparticle clusters (1206) suspended in a dielectric medium (1208). In some embodiments, and without limitation, the dielectric medium (1208) is an alcohol, a ketone (e.g., acetone), an ether, a glycol, an olefin, and/or an alkane (e.g., those alkanes with greater than three carbon atoms, e.g., tetradecane). In an embodiment, the dielectric medium (1208) is water or silicone oil. Alternatively, the dielectric medium (1208) is a sol-gel with aerogel-like properties and low thermal conductivity values that reduce heat transfer therethrough, e.g., thermal conductivity values as low as 0.013 watts per meter-degrees Kelvin (W/m-K) as compared to the thermal conductivity of water at 20 degrees Celsius (° C.) of 0.6 W/m-K. Appropriate materials are selected prior to fabricating the nanoparticle clusters (1204) and (1206). The materials selected for the nanoparticle clusters (1204) and (1206) should have work function values that are greater than the work function values for associated electrodes, such as the electrodes (1002) and (1004) of FIG. 10. For example, the work function values of the Au nanoparticle clusters (1204) and the Ag nanoparticle clusters (1206) are about 4.1 eV and 3.8 eV, respectively.

At least one layer of a dielectric coating (1210), such as a monolayer of alkanethiol material, is deposited on the Au nanoparticle clusters (1204) and the Ag nanoparticle clusters (1206) to form a dielectric barrier thereon. In an exemplary embodiment, the deposit of the dielectric coating (1210) is via electrospray. The alkanethiol material of the dielectric coating (1210) includes, but is not limited to, dodecanethiol and/or decanethiol. Additionally or alternatively, the dielectric coating (1210) may be a halogenoalkane or alkyl halide, in which one or more of the hydrogen atoms of the alkane are replaced by halogen atom(s), i.e., fluorine, chlorine, bromine, or iodine. The deposit of the dielectric coating (1210), such as alkanethiol, reduces coalescence of the nanoparticle clusters (1204) and (1206). In at least one embodiment, the nanoparticle clusters (1204) and (1206) have a diameter in the range of about 1 nm to about 3 nm. In an exemplary embodiment, the nanoparticle clusters (1204) and (1206) have a diameter of about 2 nm. The Au nanoparticle clusters (1204) and the Ag nanoparticle clusters (1206) are tailored to be electrically conductive with charge storage features (i.e., capacitive features), minimize heat transfer through associate spacer apertures, such as the spacer apertures (1106) of FIG. 11A, with low thermal conductivity values, minimize ohmic heating, eliminate space charges in the spacer apertures (1106), and prevent arcing. The plurality of Au nanoparticle clusters (1204) and the Ag nanoparticle clusters (1206) are suspended in the dielectric medium (1208). Accordingly, the nano-fluid (1202), including the suspended nanoparticle clusters (1204) and (1206), provides a conductive pathway for electrons to travel across the spacer apertures (1106) from, for example with reference to FIG. 10, the emitter electrode (1002) to the collector electrode (1004) through charge transfer. Accordingly, in at least one embodiment, a plurality of the Au nanoparticle clusters (1204) and the Ag nanoparticle clusters (1206) are mixed together in the dielectric medium (1208) to form the nano-fluid (1202), the nano-fluid (1202) residing in the apertures (1008) of FIG. 10 and/or the apertures (1106) of FIG. 11A.

The Au nanoparticle clusters (1204) according to exemplary embodiments are dodecanethiol functionalized gold nanoparticles, with an average particle size of about 1 nm to about 3 nm, at about 2% (weight/volume (grams/ml)). The Ag nanoparticle clusters (1206) are dodecanethiol functionalized silver nanoparticles, with an average particle size of about 1 nm to about 3 nm, at about 0.25% (weight/volume percent). In an embodiment, the average particle size of both the Au and Ag nanoparticle clusters (1204) and (1206) is at or about 2 nm. The Au and Ag cores of the nanoparticle clusters (1204) and (1206) are selected for their abilities to store and transfer electrons. In an embodiment, a 50%-50% mixture of Au and Ag nanoparticle clusters (1204) and (1206) are used. However, a mixture in the range of 1-99% Au-to-Ag could be used as well. Electron transfers are more likely to occur between nanoparticle clusters (1204) and (1206) with different work functions. In an exemplary embodiment, a mixture of nearly equal (molar) numbers of two different nanoparticle clusters (1204) and (1206), e.g., Au and Ag, provides good electron transfer. Accordingly, nanoparticle clusters are selected based on particle size, particle material (with the associated work function values), mixture ratio, and electron affinity.

Conductivity of the nano-fluid (1202) can be increased by increasing concentration of the nanoparticle clusters (1204) and (1206). The nanoparticle clusters (1204) and (1206) may have a concentration within the nano-fluid (1202) of, for example, about 0.1 mole/liter to about 2 moles/liter. In at least one embodiment, the Au and Ag nanoparticle clusters (1204) and (1206) each have a concentration of at least 1 mole/liter. Accordingly, in at least one embodiment, a plurality of Au and Ag nanoparticle clusters (1204) and (1206) are mixed together in a dielectric medium (1208) to form a nano-fluid (1202), the nano-fluid (1202) residing in, for example, the apertures (1008) of FIG. 10 and/or the apertures (1106) of FIG. 11A.

The stability and reactivity of colloidal particles, such as Au and Ag nanoparticle clusters (1204) and (1206), are determined largely by a ligand shell formed by the alkanethiol coating (1210) adsorbed or covalently bound to the surface of the nanoparticle clusters (1204) and (1206). The nanoparticle clusters (1204) and (1206) tend to aggregate and precipitate, which can be prevented by the presence of a ligand shell of the non-aggregating polymer alkanethiol coating (1210) enabling these nanoparticle clusters (1204) and (1206) to remain suspended. Adsorbed or covalently attached ligands can act as stabilizers against agglomeration and can be used to impart chemical functionality to the nanoparticle clusters (1204) and (1206). Over time, the surfactant nature of the ligand coatings is overcome and the lower energy state of agglomerated nanoparticle clusters is formed. Therefore, over time, agglomeration may occur due to the lower energy condition of nanoparticle cluster accumulation and occasional addition of a surfactant may be used. Examples of surfactants include, without limitation, Tween® 20 and Tween® 21.

In the case of the nano-fluid (1200) of FIG. 12 substituted for the nano-fluid (1012) of FIG. 10, electron transfer through collisions of the plurality of nanoparticle clusters (1204) and (1206) is illustrated. The work function values of the nanoparticle clusters (1204) and (1206) are much greater than the work function values of the emitter electrode (1002) (about 0.5 eV to about 2.0 eV) and the collector electrode (1004) (about 0.5 eV to about 2.0 eV). The nanoparticle clusters (1204) and (1206) are tailored to be electrically conductive with capacitive (i.e., charge storage) features while minimizing heat transfer therethrough. Accordingly, the suspended nanoparticle clusters (1204) and (1206) provide a conductive pathway for electrons to travel across the apertures (1008) from the emitter electrode (1002) to the collector electrode (1004) through charge transfer.

Thermally-induced Brownian motion causes the nanoparticle clusters (1204) and (1206) to move within the dielectric medium (1208), and during this movement the nanoparticle clusters (1204) and (1206) occasionally collide with each other and with the electrodes (1002) and (1004). As the nanoparticle clusters (1204) and (1206) move and collide within the dielectric medium (1208), the nanoparticle clusters (1204) and (1206) chemically and physically transfer charge. The nanoparticle clusters (1204) and (1206) transfer charge chemically when electrons (1212) hop between electrodes, e.g., from the electrodes (1002) and (1004) of FIG. 10, to the nanoparticle clusters (1204) and (1206) and from one nanoparticle cluster (1204) and (1206) to another nanoparticle cluster. The hops primarily occur during collisions. Due to the electric field affecting the collector electrode (104), electrons (1212) are more likely to move from the emitter electrode (1002) to the collector electrode (1004) via the nanoparticle clusters (1204) and (1206) rather than in the reverse direction. Accordingly, a net electron current from the emitter electrode (1002) to the collector electrode (1004) via the nanoparticle clusters (1204) and (1206) is the primary and dominant current of the thermal energy harvesting thermionic device (1000).

The nanoparticle clusters (1204) and (1206) transfer charge physically (i.e., undergo transient charging) due to the ionization of the nanoparticle clusters (1204) and (1206) upon receipt of an electron, and the electric field generated by the differently charged electrodes (1002) and (1004). The nanoparticle clusters (1204) and (1206) become ionized in collisions when they gain or lose an electron (1212). Positive and negative charged nanoparticle clusters (1204) and (1206) in the nano-fluid (1202) migrate to the negatively charged collector electrode (1004) and the positively charged emitter electrode (1002), respectively, providing an electrical current flow. This ion current flow is in the opposite direction from the electron current flow, but less in magnitude than the electron flow.

Some ion recombination in the nano-fluid (1202) may occur, which diminishes both the electron and ion current flow. Electrode separation may be selected at an optimum width to maximize ion formation and minimize ion recombination. In an exemplary embodiment, the electrode separation (1010) is less than about 10 nm to support maximization of ion formation and minimization of ion recombination. The nanoparticle clusters (1204) and (1206) have a maximum dimension of, for example, about 2 nm. The electrode separation distance (1010) as defined by the spacer (1006) (or the spacer (500) or (570)) has an upper limit of, for example, about 1000 nm, preferably about 100 nm, and more preferably about 20 nm, and the electrode separation distance (1010) of 20 nm is equivalent to approximately 10 nanoparticle clusters (1204) and (1206). Therefore, the electrode separation distance (1010) of about 20 nm provides sufficient space within the apertures (1008) for nanoparticle clusters (1204) and (1206) to move around and collide, while minimizing ion recombination. For example, in an embodiment, an electron can hop from the emitter electrode (1002) to a first set of nanoparticle clusters (1204) and (1206) and then to a second, third, fourth, or fifth set of nanoparticle clusters (1204) and (1206) before hopping to the collector electrode (1004). A reduced quantity of hops mitigates ion recombination opportunities. Accordingly, ion recombination in the nano-fluid (1202) is minimized through an electrode separation distance (1010) selected at an optimum width to maximize ion formation and minimize ion recombination.

When the emitter electrode (1002) and the collector electrode (1004) are initially brought into close proximity, the electrons of the collector electrode (1004) have a higher Fermi level than the electrons of the emitter electrode (1002) due to the lower work function of the collector electrode (1004). The difference in Fermi levels drives a net electron current that transfers electrons from the collector electrode (1004) to the emitter electrode (1002) until the Fermi levels are equal, i.e., the electrochemical potentials are balanced and thermodynamic equilibrium is achieved. The transfer of electrons between the emitter electrode (1002) and the collector electrode (1004) results in a difference in charge between the emitter electrode (1002) and the collector electrode (1004). This charge difference sets up the voltage of the contact potential difference and an electric field between the emitter electrode (1002) and the collector electrode (1004), where the polarity of the contact potential difference is determined by the material having the greatest work function. With the Fermi levels equalized, no net current will flow between the emitter electrode (1002) and the collector electrode (1004). Accordingly, electrically coupling the emitter electrode (1002) and the collector electrode (1004) with no external load results in attaining the contact potential difference between the electrodes (1002) and (1004) and no net current flow between the electrodes (1002) and (1004) due to attainment of thermodynamic equilibrium between the two electrodes (1002) and (1004).

The thermal energy harvesting thermionic device (1000) can generate electric power (e.g., at room temperature) with or without additional heat input. Heat added to the emitter electrode (1002) will raise its temperature and the Fermi level of its electrons. With the Fermi level of the emitter electrode (1002) higher than the Fermi level of the collector electrode (1004), a net electron current will flow from the emitter electrode (1002) to the collector electrode (1004) through the nano-fluid (1012), (1202). If the device (1000) is placed into an external circuit, such that the external circuit is connected to the electrodes (1002) and (1004), the same amount of electron current will flow through the external circuit current from the collector electrode (1004) to the emitter electrode (1002). Heat energy added to the emitter electrode (1002) is carried by the electrons (1212) to the collector electrode (1002). The bulk of the added energy is transferred to the external circuit for conversion to useful work, some of the added energy is transferred through collisions of the nanoparticle clusters (1204) and (1206) with the collector electrode (1004), and some of the added energy is lost to ambient as waste energy. As the energy input to the emitter electrode (1002) increases, the temperature of the emitter electrode (1002) increases, and the electron transmission from the emitter electrode (1002) increases, thereby generating more electron current. As the emitter electrode (1002) releases electrons onto the nanoparticle clusters (1204) and (1206), energy is stored in the thermal energy harvesting thermionic device (1000). Accordingly, the thermal energy harvesting thermionic device (1000) generates, stores, and transfers charge and moves heat energy associated with a temperature difference, where added thermal energy causes the production of electrons to increase from the emitter electrode (1002) into the nano-fluid (1012), (1202).

The nano-fluid (1202) can be substituted into the device (1000) of FIG. 10 and used to transfer charges from the emitter electrode (1002) to one of the mobile nanoparticle clusters (1204) and (1206) via intermediate contact potential differences from the collisions of the nanoparticle cluster (1204) and (1206) with the emitter electrode (1002) induced by Brownian motion of the nanoparticle clusters (1204) and (1206). Selection of dissimilar nanoparticle clusters (1204) and (1206) that include Au nanoparticle clusters (1204) and Ag nanoparticle clusters (1206) that have greater work functions of about 4.1 eV and about 3.8 eV, respectively, than the work functions of the electrodes (1002) and (1004), improves transfer of electrons to the nanoparticle clusters (1204) and (1206) from the emitter electrode (1002) to the collector electrode (1004). This relationship of the work function values of the Au and Ag nanoparticle clusters (1204) and (1206) improves the transfer of electrons to the nanoparticle clusters (1204) and (1206) through Brownian motion and electron hopping. Accordingly, the selection of materials within the thermal energy harvesting thermionic device (1000) improves electric current generation and transfer therein through enhancing the release of electrons from the emitter electrode (1002) and the conduction of the released electrons across the nano-fluid (1012), (1202) to the collector electrode (1004).

As the electrons (1212) hop from nanoparticle cluster (1204) and (1206) to nanoparticle cluster (1204) and (1206), single electron charging effects that include the additional work required to hop an electron (1212) onto a nanoparticle cluster (1204) and (1206) if an electron (1212) is already present on the nanoparticle cluster (1204) and (1206), determine if hopping additional electrons (1212) onto that particular nanoparticle cluster (1204) and (1206) is possible. Specifically, the nanoparticle clusters (1204) and (1206) include a voltage feedback mechanism that prevents the hopping of more than a predetermined number of electrons to the nanoparticle cluster (1204) and (1206). This prevents more than the allowed number of electrons (1212) from residing on the nanoparticle cluster (1204) and (1206) simultaneously. In an embodiment, only one electron (1212) is permitted on any nanoparticle cluster (1204) and (1206) at any one time. Therefore, during conduction of current through the nano-fluid (1202), a single electron (1212) hops onto the nanoparticle cluster (1204) and (1206). The electron (1212) does not remain on the nanoparticle cluster (1204) and (1206) indefinitely, but hops off to either the next nanoparticle cluster (1204) and (1206) or the collector electrode (1004) through collisions resulting from the Brownian motion of the nanoparticle clusters (1204) and (1206). However, the electron (1212) does remain on the nanoparticle cluster (1204) and (1206) long enough to provide the voltage feedback required to prevent additional electrons (1212) from hopping simultaneously onto the nanoparticle clusters (1204) and (1206). The hopping of electrons (1212) across the nanoparticle clusters (1204) and (1206) avoids resistive heating associated with current flow in a media. Notably, the thermal energy harvesting thermionic device (1000) containing the nano-fluid (1202) does not require pre-charging by an external power source in order to introduce electrostatic forces. This is due to the device (1000) being self-charged with triboelectric charges generated upon contact between the nanoparticle clusters (1204) and (1206) due to Brownian motion. Accordingly, the electron hopping across the nano-fluid (1202) is limited to one electron (1212) at a time residing on a nanoparticle cluster (1204) and (1206).

As the electrical current starts to flow through the nano-fluid (1202), a substantial energy flux away from the emitter electrode (1002) is made possible by the net energy exchange between emitted and replacement electrons (1212). The replacement electrons from an electrical conductor connected to the emitter electrode (1002) do not arrive with a value of energy equivalent to an average value of the Fermi energy associated with the material of emitter electrode (1002), but with an energy that is lower than the average value of the Fermi energy. Therefore, rather than the replacement energy of the replacement electrons being equal to the chemical potential of the emitter electrode (1002), the electron replacement process takes place in the available energy states below the Fermi energy in the emitter electrode (1002). The process through which electrons are emitted above the Fermi level and are replaced with electrons below the Fermi energy is sometimes referred to as an inverse Nottingham effect. Accordingly, a low work function value of about 0.5 eV for the emitter electrode (1002) allows for the replacement of the emitted electrons with electrons with a lower energy level to induce a cooling effect on the emitter electrode (1002).

As described this far, the principal electron transfer mechanism for operation of the device (1000) is thermionic energy conversion or harvesting. In some embodiments, thermoelectric energy conversion is conducted in parallel with the thermionic energy conversion. For example and referring to FIG. 12, an electron (1212) colliding with a nanoparticle cluster (1204) and (1206) with a first energy may induce the emission of two electrons at second and third energy levels, respectively, where the first energy level is greater than the sum of the second and third energy levels. In such circumstances, the energy levels of the emitted electrons are not as important as the number of electrons.

A plurality of thermal energy harvesting thermionic devices (1000) is distinguished by at least one embodiment having the thermoelectric energy conversion features described herein. The nano-fluid (1012), (1202) is selected for operation of the thermal energy harvesting thermionic devices (1000) within one or more temperature ranges. In an embodiment, the temperature range of the associated thermal energy harvesting thermionic device (1000) is controlled to modulate a power output of the device (1000). In general, as the temperature of the emitter electrode (1002) increases, the rate of thermionic emission therefrom increases. The operational temperature ranges for the nano-fluid (1202) are based on the desired output of the thermal energy harvesting thermionic device (1000), the temperature ranges that optimize thermionic conversion, the temperature ranges that optimize thermoelectric conversion, and fluid characteristics. Therefore, different embodiments of the nano-fluid (1202) are designed for different energy outputs of the device (1000).

For example, in an embodiment, the temperature of the nano-fluid (1012), (1202) is maintained at less than 250° C. to avoid deleterious changes in energy conversion due to the viscosity changes of the dielectric medium (1208) above 250° C. In an embodiment, the temperature range of the nano-fluid (1202) for substantially thermionic emission only is approximately room temperature (i.e., about 20° C. to about 25° C.) up to about 70-80° C., and the temperature range of the nano-fluid (1202) for thermionic and thermo-electric conversion is above 70-80° C., with the principle limitations being the temperature limitations of the materials. The nano-fluid (1202) for operation including thermoelectric conversion includes a temperature range that optimizes the thermoelectric conversion through optimizing the power density within the thermal energy harvesting thermionic device (1000), thereby optimizing the power output of the device (1000). In at least one embodiment, a mechanism for regulating the temperature of the nano-fluid (1202) includes diverting some of the energy output of the device (1000) into the nano-fluid (1202). Accordingly, the apertures (1008) of specific embodiments of the thermal energy harvesting thermionic device (1000) may be filled with the nano-fluid (1202) to employ thermoelectric energy conversion with thermionic energy conversion above a particular temperature range, or thermionic energy conversion by itself below that temperature range.

As described herein, in at least one embodiment, the dielectric medium (1208) has thermal conductivity values less than about 1.0 watt per meter-degrees Kelvin (W/m-K). In at least one embodiment, the thermal conductivity of the dielectric medium (1208) is about 0.013 watt per meter-degrees Kelvin (W/m-K), as compared to the thermal conductivity of water at about 20 degrees Celsius (° C.) of about 0.6 W/m-K. Accordingly, the nano-fluid (1202) minimizes heat transfer, such as through the apertures (1008) of FIG. 10, with low thermal conductivity values. Since the heat transport in a low thermal conductivity nano-fluid (1202) can be small, a high temperature difference between the two electrodes, e.g., the electrodes (1002) and (1004), can be maintained during operation. These embodiments are designed for thermal energy harvesting thermionic devices that employ thermionic emission where minimal heat transfer through the nano-fluid (1012), (1202) is desired.

As shown in FIG. 10, the thermal energy harvesting thermionic device (1000) has an aperture (1008) with a distance (1010) between electrodes (1002) and (1004) that is within a range of, for example, about 1 nm to about 20 nm. In a portion of the electrode separation distance (1010) of about 1 nm to about less than 10 nm, thermal conductivity values and electrical conductivity values of the nano-fluid (1012), (1202) are enhanced beyond those conductivity values attained when the predetermined distance of the cavity (1008) is greater than about 100 nm. This enhancement of thermal and electrical conductivity values of the nano-fluid (1012), (1202) associated with the distance (1010) of about 1 nm to 10 nm as compared to a distance (1010) greater than 100 nm is due to a plurality of factors.

Examples of a first factor include, but are not limited to, enhanced phonon and electron transfer between the plurality of nanoparticle clusters (1204) and (1206) within the nano-fluid (1202), enhanced phonon and electron transfer between the plurality of nanoparticle clusters (1204) and (1206) and the first electrode (1002), and enhanced phonon and electron transfer between the plurality of nanoparticle clusters (1204) and (1206) and the second electrode (1004).

A second factor is an enhanced influence of Brownian motion of the nanoparticle clusters (1204) and (1206) in a confining environment between the electrodes (1002) and (1004) to, e.g., less than about 10 nm. As the distance (1010) between the electrodes (1002) and (1004) decreases below about 10 nm, fluid continuum characteristics of the nano-fluid (1012), (1202) with the suspended nanoparticle clusters (1204) and (1206) is altered. For example, as the ratio of particle size to volume of the apertures (1008) increases, random and convection like effects of Brownian motion in a dilute solution dominate. Therefore, collisions of the nanoparticle clusters (1204) and (1206) with the surfaces of other nanoparticle clusters (1204) and (1206) and the electrodes (1002) and (1004) increase thermal and electrical conductivity values due to the enhanced phonon and electron transfer.

A third factor is the at least partial formation of matrices of the nanoparticle clusters (1204) and (1206) within the nano-fluid (1202). Under certain conditions, the nanoparticle clusters (1204) and (1206) will form matrices within the nano-fluid (1202) as a function of close proximity to each other with some of the nanoparticle clusters (1208) remaining independent from the matrices. In an embodiment, the formation of the matrices is based on the factors of time and/or concentration of the nanoparticle clusters (1204) and (1206) in the nano-fluid (1202).

A fourth factor is the predetermined nanoparticle clusters (1204) and (1206) density, which in an embodiment is about one mole per liter. Accordingly, apertures (1008) containing the nano-fluid (1202) with a distance (1010) of about 1 nm to less than about 10 nm causes an increase in the thermal and electrical conductivity values of the nano-fluid (1202) therein.

In addition, the nanoparticle clusters (1204) and (1206) have a small characteristic length, e.g., about 2 nm, and they are often considered to have only one dimension. This characteristic length restricts electrons in a process called quantum confinement, which increases electrical conductivity. The collision of particles with different quantum confinement facilitates transfer of charge to the electrodes (1002) and (1004). The thermal energy harvesting thermionic device (1000) has an enhanced electrical conductivity value greater than about 1 Siemens per meter (S/m) as compared to the electrical conductivity of drinking water of about 0.005 S/m to about 0.05 S/m. Also, the embodiments of the device (1000) with the enhanced thermal conductivity have a thermal conductivity value greater than about 1 W/m-K as compared to the thermal conductivity of water at 20 degrees Celsius (° C.) of about 0.6 W/m-K.

Thermionic emission of electrons (1212) from the emitter electrode (1002) and the transfer of the electrons (1212) across the nano-fluid (1202) from one nanoparticle cluster (1204) and (1206) to another nanoparticle cluster (1204) and (1206) through hopping are both quantum mechanical effects.

Release of electrons from the emitter electrode (1002) through thermionic emission as described herein is an energy selective mechanism. A thermionic barrier in the apertures (1008) between the emitter electrode (1002) and the collector electrode (1004) is induced through the interaction of the nanoparticles (1204) and (1206) inside the apertures (1008) with the electrodes (1002) and (1004). The thermionic barrier is at least partially induced through the number and material composition of the plurality of nanoparticle clusters (1204) and (1206). The thermionic barrier induced through the nano-fluid (1202) provides an energy selective barrier on the order of magnitude of about 1 eV. Accordingly, the nano-fluid (1202) provides an energy selective barrier to electron emission and transmission.

To overcome the thermionic barrier and allow electrons (1212) to be emitted from the emitter electrode (1002) above the energy level needed to overcome the barrier, materials for the emitter electrode (1002) and the collector electrode (1004) are selected for their work function values and Fermi level values. The Fermi levels of the two electrodes (1002) and (1004) and the nanoparticle clusters (1204) and (1206) will try to align by tunneling electrons (1212) from the electrodes (1002) and (1004) to the nanoparticle clusters (1204) and (1206). The difference in potential between the two electrodes (1002) and (1004) (described elsewhere herein) overcomes the thermionic barrier, and the thermionic emission of electrons (1212) from the emitter electrode (1002) occurs with sufficient energy to overcome the thermionic block. Notably, and in general, for cooling purposes, removing higher energy electrons from the emitter electrode (1002) causes the emission of electrons (1212) to carry away more heat energy from the emitter electrode (1002) than is realized with lower energy electrons. Accordingly, the energy selective barrier is overcome through the thermionic emission of electrons at a higher energy level than would be otherwise occurring without the thermionic barrier.

Once the electrons (1212) have been emitted from the emitter electrode (1002) through thermionic emission, the thermionic barrier continues to present an obstacle to further transmission of the electrons (1212) through the nano-fluid (1202). Smaller gaps on the order of about 1 nm to about 10 nm, as compared to those gaps in excess of 100 nm, facilitate electron hopping, i.e., field emission, of short distances across the apertures (1008). Energy requirements for electron hopping are much lower than the energy requirements for thermionic emission; therefore, the electron hopping has a significant effect on the energy generation characteristics of the device (1000). The design of the nano-fluid (1202) enables energy selective tunneling, e.g. electron hopping, that is a result of the barrier (which has wider gap for low energy electrons) which results in electrons above the Fermi level being a principal hopping component. The direction of the electron hopping is determined through the selection of the different materials for the electrodes (1002) and (1004) and their associated work function and Fermi level values. The electron hopping across the nano-fluid (1202) transfers heat energy with electrons (1212) across the apertures (1008) while maintaining a predetermined temperature gradient such that the temperature of the nano-fluid (1202) is relatively unchanged during the electron transfer. Accordingly, the emitted electrons transport heat energy from the emitter electrode (1002) across the apertures (1008) to the collector electrode (1004) without increasing the temperature of the nano-fluid (1202).

In an embodiment, the thermionic power harvesting device (1000) is configurable with respect to the physical dimensions therein. In an exemplary embodiment, the device (1000) has a length measurement, in a direction along the X-axis in FIG. 10, of approximately 6 inches, although other lengths are contemplated, and a width measurement, in a direction along the Z axis in FIG. 10, of approximately 6 inches, although other widths are contemplated. A thickness of the thermionic power harvesting device is approximately 0.005 mm to about 2.0 mm, for example about 1.0 mm. In an exemplary embodiment such measurements should not be considered limiting. For example, in an exemplary embodiment, the physical dimensions may be expanded or reduced to accommodate operational aspects of the device.

Referring to FIG. 13, a diagram (1300) is provided illustrating a schematic perspective view of an embodiment of a thermal energy harvesting thermionic device (1390) that may be incorporated into the respective apparatus of FIGS. 1-8. The thermal energy harvesting thermionic device (1390) is not shown to scale, and the circuit illustrated in FIG. 13 omits certain features of FIGS. 1-8, such as the electrical energy storage device (e.g., capacitor) or photoelectric cell, the heating element, the temperature sensor, the controller, and the charging circuit. The power harvesting device (1390) is manufactured with a plurality of layers of materials. In an embodiment, the power harvesting device (1390) is manufactured to include four layers. A first layer (1302) is referred to as a casing or sheathing that protects one or more of the inner layers and facilitates heat transfer in and out of the device (1390). In an embodiment, the first layer (1302) is manufactured from a thermally conductive and electrically insulating material. A second layer (1304) includes the emitter electrode, a third layer (1306) includes the separation material (also referred to herein as a standoff and spacer), and a fourth layer (1308) includes the collector electrode. In an embodiment, the third layer (1306) is referred to herein as a spacer. The emitter electrode (1304), the spacer (1306), and the collector electrode (1308) are fabricated and configured as shown and described in FIGS. 10-12. The separation material (1306), e.g., the third layer, contains nano-fluid, such as the nano-fluid (1012) of FIG. 10 and (1202) of FIG. 12, positioned in the apertures (1008) and (1106). The outer casing (1302), e.g., the first layer, is in direct contact with the emitter electrode (1304), e.g., the second layer, and the emitter electrode (1304) and the collector electrode (1308), e.g., the fourth layer, are in direct contact with the spacer (1306). The layers (1302), (1304), (1306), and (1308) are shown peeled away for clarity. In an embodiment, the layers (1302), (1304), (1306), and (1308) define a composite structure configured as a sheet (1310). Accordingly, the outer casing (1302) is in contact with the emitter electrode (1304) to provide heat transfer, protective, and sealing features to the device (1390).

The thermionic power harvesting device (1390) is shown herein with an at least partially planar configuration with a defined radius (1312) extending from an end of an aperture (1318) to an outermost surface (1316) of the device (1390). It should be understood that various configurations may be practiced. As shown herein, the aperture (1318) has a planar or relatively planar geometric characteristic, and is hereinafter referred to as a planar aperture. The planar aperture (1318) has geometric properties, including a first base area (1320) and an opposing second base area (1322), with the planar aperture extending from the first base area (1320) to the second base area (1322). In an embodiment, the distance between the first base area (1320) and the second base area (1322) is referred to as a first distance. In an embodiment, a structural member (1324) is inserted into and received by the planar aperture (1318). The structural member (1324) is received by and positioned within the aperture (1318). In an embodiment, the structural member (1324) received by and positioned in the aperture (1318) extends beyond the area defined by the aperture (1318). In an embodiment, the structural member (1324) is fabricated from one or more materials that are both thermally and electrically conductive, as well as chemically compatible with the materials of the layers (1302), (1304), (1306), and (1308). In other embodiments, the structural member (1324) is fabricated from materials that are either thermally or electrically conductive. Accordingly, the structural member (1324) is configured with mechanical and electrical properties. Although the structural member (1324) is illustrated as a flat, e.g. planar, plate, it should be understood that the structural member (1324) may have other configurations.

The fourth layer (1308), i.e., the collector electrode, is electrically coupled to the structural member (1324) to provide at least a partial electrical flow path. The composite sheet (1310) extends from the structural member (1324) in a wrapped or rolled configuration, where the wrapped configuration has a common center defined by the planar aperture (1318) to further define a concentric configuration. The planar aperture (1318) further defines a toroidal configuration with respect to the wrapped configuration of the composite sheet (1310). Accordingly, the at least partially planar thermionic power harvesting device (1390) has characteristics that are substantially toroidal.

In an embodiment, the thermionic power harvesting device (1390) has a first measurement (1326), referred to as length, of approximately 10 mm to about 2.0 m, lengths outside this range are contemplated. A thickness of the composite layer (1310) (i.e., collective thickness of the layers (1302), (1304), (1306), and (1308)) is approximately 0.005 mm to about 2.0 mm. A thickness (1330) of the collector electrode (1308) is approximately 0.005 mm to less than 2.0 mm. A thickness (1332) of the spacer (1306) is approximately 1.0 nm to about 10 microns. A thickness (1334) of the emitter electrode (1304) is approximately 0.005 mm to less than 2.0 mm. A thickness (1336) of the outer casing (1302) is approximately 0.005 mm to less than 2.0 mm. The composite sheet (1310) is defined by a first measurement, which is referred to as a composite length, ranging from approximately 10 mm to 2.0 m, for example. Other embodiments include any dimensional characteristics that enable operation of the thermionic generation device (1390) as described herein.

As further shown, an electrical circuit (1350) is connected to the thermionic power harvesting device (1390). The circuit (1350) includes an electrical conductor (1352) that is electrically connected to the structural member (1324) that is electrically connected to the collector electrode (1308). The circuit (1350) further includes at least one electrical load (1356), such as a power-consumption device (e.g., (120) of FIG. 1) or a rechargeable power storage device (e.g., (118) of FIG. 1) connected to the conductor (1352). When the thermionic power harvesting device (1390) is generating electricity, electrical current (1358) (using conventional flow notation) is transmitted through the circuit (1350) in an opposite direction to the electron current. As discussed above, the electrons flow within the device (1390) from the emitter electrode (1304) to the collector electrode (1308). For example, a single device (1390) can generate a voltage within a range extending between about 0.5 volts and 1.0 volts, depending on the contact potential difference (discussed further herein) induced between the emitter electrode (1304) and the collector electrode (1308) as a function of the emitted and collector materials. In an embodiment, the device (1390) generates about 0.90 volts. The device (1390) can generate an electrical current within a range of approximately 5 amperes (amps) to approximately 10 amps. In an embodiment, the device (1390) generates about 7.35 amps. Further, in an embodiment, the device (1390) generates approximately 2.5 watts to approximately 10 watts. In an embodiment, the device (1390) generates about 6.6 watts. A plurality of the devices (1390) may be electrically connected in series for a specific voltage or in parallel for a specific current, or in series and parallel to satisfy both the voltage and current requirements. Accordingly, as described further herein, an arrangement of the devices (1390) is scalable to provide sufficient electrical power from the watt range to the megawatt range for a variety of applications.

The structural member (1324) performs both heat transfer and electrical conduction actions when the thermionic power harvesting device (1390) is in service generating electricity. The structural member (1324) is electrically coupled to the circuit (1350) to transmit the electrical power generated within the device (1390) along the conductor (1352) to the electrical load (1356).

In the embodiment shown in FIG. 13, the structural member (1324) is shown operably coupled to a heat dissipating device, shown herein as a heat sink or a heat exchanger (1360), which in an exemplary embodiment may be a microstructured array heat exchanger. Specifically, the collector electrode (1308) is in direct contact with the structural member (1324). In an embodiment, the heat exchanger or the heat sink (1360) is positioned between the structural member (1324) and the electrical load (1356), and optionally in contact with the structural member (1324), to cool the conductor (1352) and avoid thermal damage that could otherwise be caused by the transfer of thermal energy by the conductor (1352) to the electrical load (1356). In another exemplary embodiment, the heat transfer to air is adequate in ambient conditions, so that the use or need for a heat exchanger can be mitigated or eliminated. The heat exchanger or heat sink (1360) may be located internal or external to the housing, e.g., housing (104), (204), (304), (404), (504), (604), (704), and/or (804).

The thermionic power harvesting device (1390) generates electric power through harvesting heat energy (1364). As described in further detail herein, the emitter electrode (1304) receives heat energy (1364) from sources that include, without limitation, heat generating sources (1365) (e.g., heating element/resistor (108) of FIG. 1), and generates the electric current (1358), which is transmitted through the circuit (1350) to the load (1356).

In FIG. 13, reference numeral (1370A) represents a first embodiment of a housing. The housing (1370A) is shown enclosing the heat sink or heat exchanger (1360). Reference numeral (1370B) in FIG. 13 represents a second embodiment of a housing. The heat sink or heat exchanger (1360) is outside or external to the housing (1370B) in FIG. 13. It should be understood that other components shown internal to the housing (1370A) or (1370B) in FIG. 13 can be positioned external to the housing (1370A) or (1370B). For example, the load (1356), the heating element (1365), the temperature sensor (not shown in FIG. 13), and/or the controller (not shown in FIG. 13) can be internal or external to the housing (1370A) or (1370B).

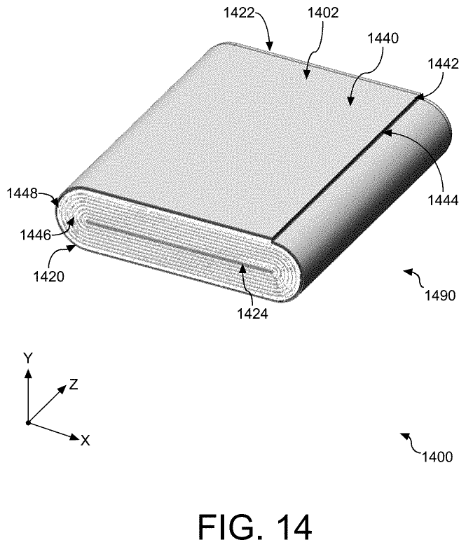

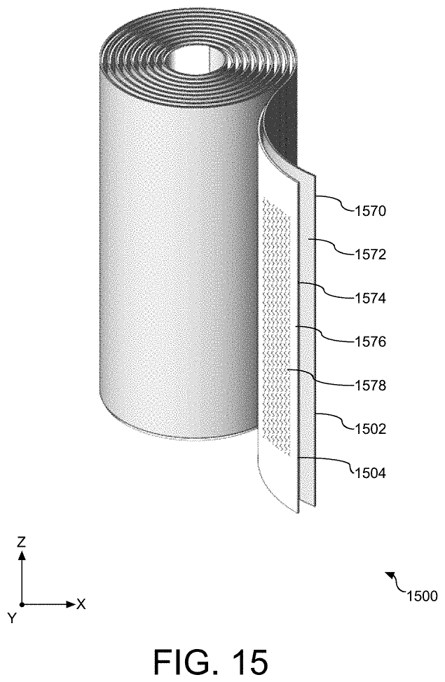

Referring to FIG. 14, a schematic drawing (1400) is provided illustrating a perspective view of a thermionic power harvesting device (1490) similar to the device (1390). In an embodiment, an outer casing (1402) includes multiple layers (similar to layer 1302 of FIG. 13) of outer casing material to fabricate the outer casing (1402) with an enhanced robustness. The outer casing (1402) of the device (1490) includes an external surface (1440) that includes a seam (1442) defined by one or more layers (such as layer (1302) of FIG. 13) of the outer casing (1402). In an embodiment, the seam (1442) is defined by a composite structure, such as the composite structure (1310) of FIG. 13. The seam (1442) is shown receiving a sealant (1444) to prevent ingress of contaminants and egress of device materials through the seam (1442). In an embodiment, the sealant (1442) is non-conductive to prevent short circuiting, such as between the electrodes (1304) and (1308) of FIG. 13. In an embodiment, the sealant (1444) is antimony-based. In another embodiment, the sealant (1444) is a beryllium—based sealant. In still another embodiment, the sealant (1444) is a polymer—based sealant. In another embodiment, the sealant (1444) is manufactured from a material that does not impede or prevent operation of a thermionic power harvesting device (1490) as described herein.

A first base area (1420) receives a sealant (1446) that extends between a rim (1448) defined by the outer casing (1402) and a structural member (1424), which is the same as or similar to the structural member (1444) described above. In an embodiment, the sealant (1446) is substantially similar to the sealant (1444) with respect to composition and function. In an embodiment, the sealant (1446) is different from the sealant (1444). The sealant (1446) is also applied to a second base area (1422), oppositely disposed from the first base area (1420). In an embodiment, the second end area (1422) has a similar configuration to the first base area (1420). The sealant (1446) functions to protect electrodes (e.g., the electrodes (1304) and (1308)), spacer (e.g., the spacer (1306)), and nano-fluid (e.g., the nano-fluid (1202)) from environmental factors, such as debris, that may induce a short circuit between electrodes (e.g., the electrodes (1304) and (1308)) or contaminate the nano-fluid (1202).

In addition, as described herein with respect to FIG. 13, and described further with respect to FIGS. 11A and 11B, the electrodes (1304) and (1308) (equivalent to the electrodes (1162) and (1164), respectively) are offset distances (equivalent to distances (1136) and (1148), respectively), from the edges (1114) and (1116) of the spacer (1306). As shown in FIG. 14, the non-conducting sealant (1446) resides around the lateral side edges (similar to side edges (1130) of the electrode (1162) and the lateral side edges (1142) of the electrode (1164)) that extend distances (equivalent to distances (1136) and (1148)) beyond the spacer (1100), (1170)), respectively. Accordingly, the thermionic power harvesting device (1490) is shown herein with sealants (1444) and (1446) that provide environmental protection for the device (1490) and electrical insulation for the electrodes (1304) and (1308).

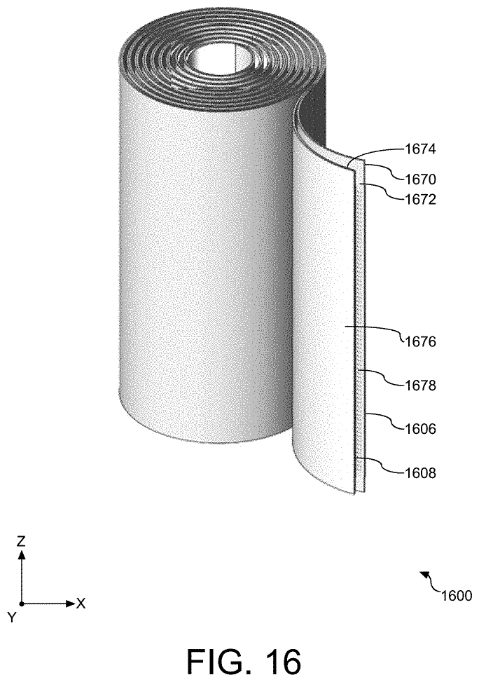

In an embodiment, the thermionic power harvesting device (1000) is manufactured from different prefabricated materials. FIG. 15 shows a perspective view of a first repository or roll (1500) of layered materials (1502) and (1504), e.g., the first and second layers, that may be used to manufacture the thermionic power harvesting devices (1000). FIG. 16 illustrates a perspective view of a second repository or roll (1600) of layered materials (1606) and (1608), e.g. the third and fourth layers, that may be used in combination with the first repository (1500) to manufacture the thermionic power harvesting devices (1000).

Referring to FIG. 15, a first layer (1502) is equivalent to an outer casing of the thermionic power harvesting device, and is hereon referred to as outer casing (1502). The outer casing (1502) is the equivalent to the first backing (1016) of FIG. 10. Similarly, a second layer (1504) is equivalent to the emitter electrode (1018) and is hereon referred to as emitter electrode (1504). The outer casing (1502) includes a first surface (1570) that defines an external surface of the thermionic power harvesting device (1000). The outer casing (1502) also includes a second surface (1572) that contacts the emitter electrode (1504). The emitter electrode (904) includes a first surface (1574) contacting the second surface (1572) of the outer casing (902). The emitter electrode (1504) also includes a second surface (1576). In an embodiment, the second surface (1576) is at least partially coated with Cs₂O (1578), which in an embodiment is pre-applied to the second surface (1576). In an embodiment, the Cs₂O (1578) is applied to the second surface (1576) during manufacturing of the thermionic power harvesting device.

Referring to FIG. 16, a third layer (1606) is equivalent to a separation material (such as the spacer 1006) of FIG. 10), and is hereon referred to as separation material (1606). In an embodiment, the separation material (1606) is, e.g., a dielectric material, and the separation material (1606) is impregnated with a nano-fluid, such as nano-fluid (1202) discussed herein. Similarly, a fourth layer (1608) is equivalent to a collector electrode and is hereon referred to as collector electrode (1608). The separation material (1606) includes a first surface (1670) that contacts the second surface (1576) of the emitter electrode (1504) of FIG. 15. The separation material (1606) also includes a second surface (1672). The collector electrode (1608) includes a first surface (1674) contacting the second surface (1672) of the separation material (1606). The collector electrode (1608) also includes a second surface (1676). In an embodiment, the first surface (1674) is at least partially coated with Cs₂O (1678), which in an embodiment is pre-applied to the first surface (1674). In an embodiment, the Cs₂O (1678) is applied to the first surface (1674) during manufacturing of the thermionic power harvesting device.

In an embodiment, rather than manufacturing the thermionic power harvesting devices using the two repositories or rolls (1500) and (1600), each of the layers (1502), (1504), (1606), and (1608) are dispensed from an individual repository or roll for each layer. In another embodiment, rather than using a separation material (1606) in the form of a solid material, the separation material (1606) is applied to either the second surface (1576) of the emitter electrode (1504) or the first surface (1674) of the collector electrode (1608). In an embodiment, the solid material is a sheet or a web. In an embodiment, the separation material (1606) is applied to both of the surfaces (1576) and (1674). In an embodiment, the separation material (1606) is pre-applied to the electrodes (1504) and (1608). In an embodiment, the separation material (1606) is applied to the electrodes (1504) and (1608) at the time of manufacture of the thermal energy harvesting thermionic device. In an embodiment, the separation material (1606) is a fluid applied through one or more electrospray devices (e.g., FIG. 20). In an embodiment, the separation material (1606) is applied through any method that enables operation of devices as described herein.

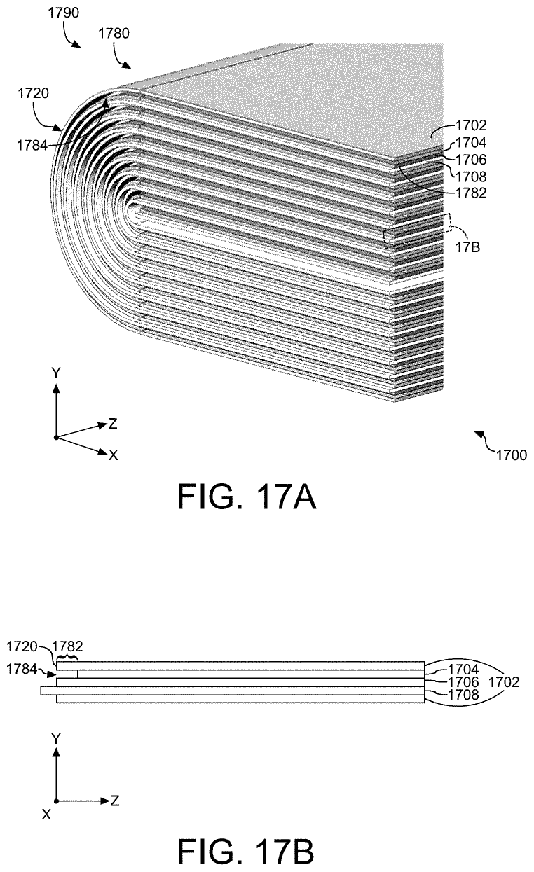

Referring to FIGS. 17A and 17B, a diagram (1700) is provided illustrating an enlarged perspective view of a first portion (1780) of a thermionic power harvesting device (1790) according to an embodiment. The device (1790) is constructed of a four-layer composite including the four layers of FIGS. 15 and 16, collectively, wound about a structural member (1724), which may be conductive. While shown as an oblong roll, it should be understood that the wound structure may be configured in other configurations, including as a rolled cylinder. An outer casing (1702), an emitter electrode (1704), a spacer (1706), and a collector electrode (1708) are shown stacked on one another to provide a composite structure, which in an embodiment is a sheet wrapped about the structure member (1724). As best shown in FIG. 17B, the emitter electrode (1704) is offset (1782) with respect to the spacer (1706). The emitter electrode (1704) is recessed or offset in the Z-dimension with respect to a first base area (1720) at least partially defined by the outer casing (1702), the spacer (1706), and the collector electrode (1708). The depression or offset (1782) of the emitter electrode (1704) defines a cavity (1784) between each adjacent layer of the spacer (1706) and each adjacent layer of the outer casing (1702). In addition to the set back of the emitter electrode (1704), the collector electrode (1708) extends beyond the adjacent spacer (1706) in the Z-dimension. In an embodiment, rather than the emitter electrode (1704), the collector electrode (1708) is depressed or offset in the Z-dimension with respect to the first base area (1720). In an embodiment, an edge of the collector electrode (1708) is approximately flush, e.g., co-planar, with the edge of the spacer (1706) to partially define the first base area (1720) with no offset. As described herein with respect to FIGS. 17A and 17B, a sealant may be applied to the end area (1720) to cover the edges of the emitter and collector electrodes (1704) and (1708), respectively, proximate the end area (1720) and fill in the cavity (1784) with a non-conductive material to further electrical isolation between the electrodes (1704) and (1708).

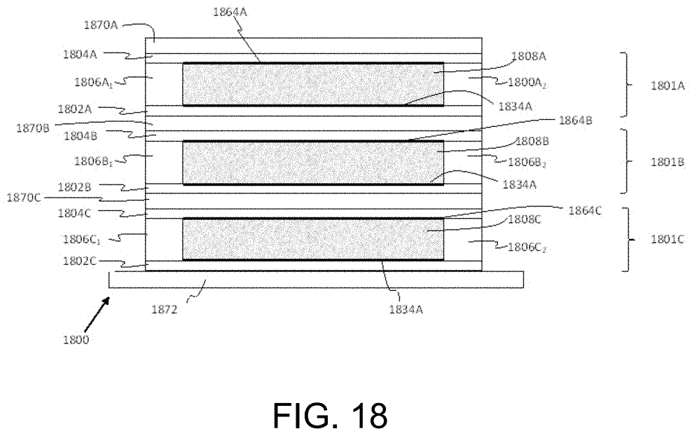

FIG. 18 is a cross-sectional view of a thermionic power harvesting device, generally designated by reference numeral (1800), according to an exemplary embodiment. Unlike the wound embodiments described above in connection with FIGS. 13-17B, the thermionic power harvesting device (1800) of FIG. 18 comprises a plurality of harvester units (1801A), (1801B), and (1801C) layered/stacked on one another. The harvester units (1801A), (1801B), and (1801C) are serially connected to one another and separated from one another by insulating layers.

The first (top) harvester unit (1801A) includes an emitter electrode (cathode) (1802A) having a coating (1834A), a collector electrode (anode) (1804A) having a coating (1864A), and a chamber (or aperture) interposed between the electrodes (1802A) and (1804A) filled with nano-fluid (1808A) and surrounded on opposite sides by insulating spacers (1806A₁) and (1806A₂). The second (middle) harvester unit (1801B) includes an emitter electrode (cathode) (1802B) having a coating (1834B), a collector electrode (anode) (1804B) having a coating (1864B), and a chamber (or aperture) between the electrodes (1802B) and (1804B) filled with nano-fluid (1808B) and surrounded on opposite sides by insulating spacers (1806B₁) and (1806B₂). The third (bottom) harvester unit (1801C) includes an emitter electrode (cathode) (1802C) having a coating (1834C), a collector electrode (anode) (1804C) having a coating (1864C), and a chamber (or aperture) between the electrodes (1802C) and (1804C) filled with nano-fluid (1808C) and surrounded on opposite sides by insulating spacers (1806C₁) and (1806C₂).

A first insulating layer (1870A) is positioned above the first harvester unit (1801A). A second insulating layer (1870B) is interposed between the first harvester unit (1801A) and the second harvester unit (1801B). A third insulating layer (1870C) is interposed between the second harvester unit (1801B) and the third harvester unit (1801C). A conductive plate (1872) is positioned blow the third harvester unit (1801C) as a thermal conductor for transmitting heat from the heat generating source (e.g., heating element (108) of FIG. 1) to the thermionic power harvesting device (1800). In another embodiment, reference numeral (1872) may be the heat generating source, e.g., the heating element (108) of FIG. 1.

The emitter electrodes (cathodes) (1802A), (1802B), and (1802C) may be made of any of the materials described herein. In an exemplary embodiment, the emitter electrodes (1802A), (1802B), and (1802C) are made of a copper foil coated with platinum (Pt). The emitter electrode coatings (1834A), (1834B), and (1834C) may be comprised of cesium oxide, and may cover, for example, about 60 to 80 percent of the surface area of their respective emitter electrodes. The collector electrodes (anodes) (1804A), (1804B), and (1804C) likewise may be made of any of the materials described herein. In an exemplary embodiment, the collector electrodes (1804A), (1804B), and (1804C) are made of tungsten foil. The collector electrode coatings (1864A), (1864B), and (1864C) may be comprised of cesium oxide, and may cover, for example, about 60 to about 80 percent of the surface area of their respective collector electrodes.

The nano-fluids (1808A), (1808B), and (1808C) may be, for example, any of the materials described above in connection with FIG. 12. In an exemplary embodiment, the nano-fluids (1808A), (1808B), and (1808C) include polymer-coated gold and silver nanoparticles. In an exemplary embodiment, the polymer coating of the nanoparticles is a halogenoalkane or alkyl halide, particularly those having boiling points above 220° C.

The insulating spacers (1806A₁), (1806A₂), (1806B₁), (1806B₂), (1806C₁), and (1806C₂) and the insulating layers (1870A), (1870B), and (1870C) may be comprised of, for example, an alkane-thiol. The spacers may have a multi-layer (e.g., five-layer) structure, with each layer at least one micron in thickness.

For the purposes of illustration, the thermionic power harvesting device (1800) has been shown with three harvester units (1801A), (1801B), and (1801C) stacked on one another. It should be understood that the device (1800) may include fewer (two) or more thermionic energy harvester units than shown. Although FIG. 18 has been discussed in connection with a serial (or daisy-chained) connection of the thermionic energy harvesting units (1801A), (1801B), and (1801C), it should be understand that the units may be connected in parallel or serial-parallel. Further, the thermionic energy harvesting units (1801A), (1801B), and (1801C) may be positioned relative to one another in configurations other than the stacked configuration of FIG. 18. For example, the thermionic energy harvesting units (1801A), (1801B), and (1801C) may be positioned adjacent one another.

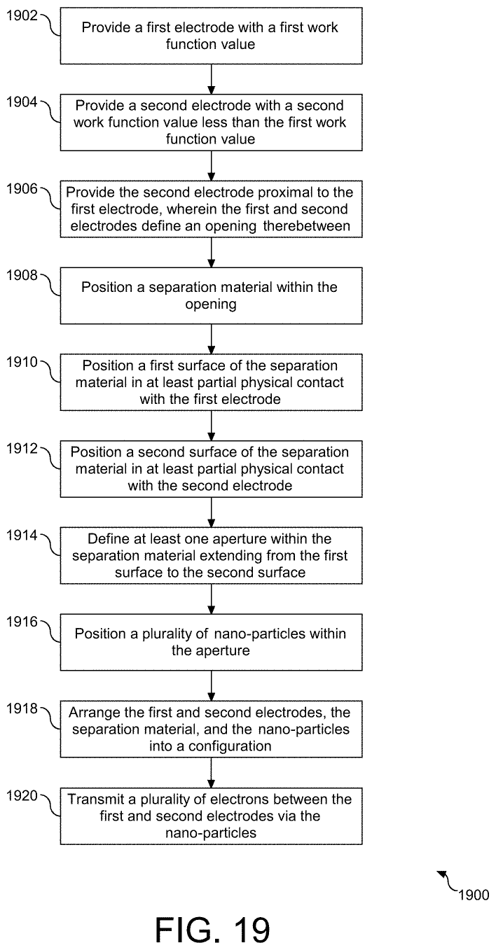

Referring to FIG. 19, a flowchart (1900) is provided illustrating a process according to an embodiment for generating electric power with the thermal energy harvesting thermionic device. As described herein, a first electrode having a first work function value is provided (1902) and a second electrode having a second work function value is provided (1904). The work function value of the second electrode is less than the work function value of the first electrode. The first electrode and the second electrode are proximally positioned a predetermined distance from each other, i.e., about 1 nm to less than about 20 nm, to define an opening there between (1906). A separation material is positioned within the opening (1908). A first surface of the separation material is positioned in at least partial physical contact with the first electrode (1910), and a second surface of the separation material is positioned in at least partial physical contact with the second electrode (1912). At least one aperture is defined within the separation material, with the aperture extending from the first surface to the second surface (1914). A medium (e.g., nano-fluid) comprising a plurality of nanoparticles is positioned within the aperture(s) (1916). The first and second electrodes, the separation material, and the nanoparticles are arranged in a configuration (1918), and a plurality of electrons is transmitted between the first and second electrodes via the nanoparticles (1920).

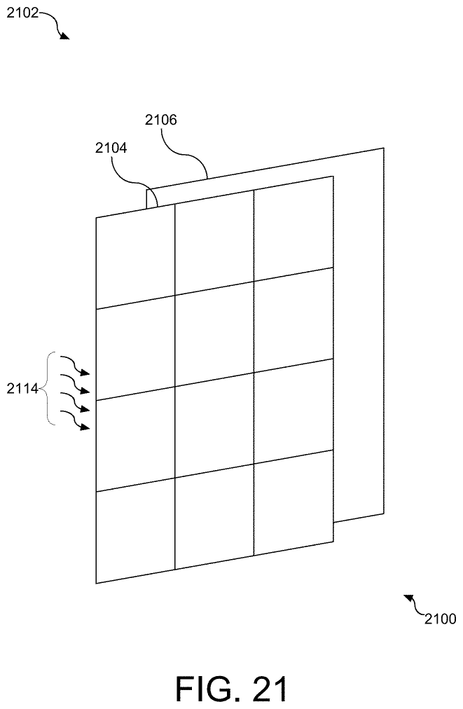

The thermal energy harvesting thermionic devices described herein can be integrated with or otherwise associated with multiple energy-harvesting devices to produce a greater energy-density device. The thermal energy harvesting thermionic devices described herein can be integrated with or otherwise associated with other heat and/or electrical sources. FIG. 21 shows an assembly (2102) including a solar cell array (2104) for mounting on an apparatus housing (2106). As light, represented in FIG. 21 by curvy arrows (2114), is incident on the solar cell array (2104), electrical energy generated by the solar cell array (2104) is transmitted into the apparatus housing (2106). The electrical energy may be used to run a current through the heat generating source (e.g., heating element (108) of FIG. 1) to generate heat or to charge the electrical energy storage device (e.g., device (106) of FIG. 1).

As described herein, exemplary embodiments are directed generally to an apparatus including an energy source, and more particularly is directed to a thermal energy harvesting thermionic device. Ionization is provided therein by the combination of electron tunneling and thermionic emission of the thermal energy harvesting thermionic device. Charge transfer therein is affected through conductive nanoparticles suspended in a fluid, i.e., a nano-fluid, undergoing collisions driven by thermally-induced Brownian motion. The design of the thermal energy harvesting thermionic device enables energy extraction from the heat generating source of the apparatus. To this end, the electrodes are proximally positioned to allow electrons to travel the distance between them. These electrons emitted at a wide range of temperatures proceed across the gap due to the nano-fluid providing a conductive pathway for the electron emission, reducing or minimizing heat transfer to maintain a nano-scale heat engine, and preventing arcing.

With respect to thermionic converters, the electrical efficiency of exemplary embodiments of these devices depends on low work function materials deposited on the emitter electrode (cathode) and the collector electrode (anode). The efficiency of two low work function electrodes can be increased by developing cathodes with sufficient thermionic emission of electrons operating even at room temperature. These low work function cathodes and anodes provide copious amounts of electrons. Similarly, a tunneling device includes two low work function electrodes separated by a designed nano-fluid. Cooling by electrode emission refers to the transport of hot electrons across the nano-fluid gap, from the object to be cooled (cathode) to the heat rejection electrode (anode). Thus, the coupling of several technologies, including: the electrospray-deposited two low work function electrodes include, for example, cesium-oxide on both electrode surfaces; an energy selective electron-transfer thermionic emission and quantum hopping of electrons; a nano-fluid that is tailored as a thermoelectric element to conduct electricity while minimizing heat transfer within the device; and thermal communication from the anode electrical connection that is in thermal contact with the device and the outside heat reservoir, such as a heat sink or a heat exchanger, produces a thermionic power generator according to an exemplary embodiment.

The thermal energy harvesting thermionic devices of exemplary embodiments described herein facilitate generating electrical energy via a long-lived, constantly-recharging, battery-like device for any size-scale electrical application. Thermal energy harvesting thermionic devices of exemplary embodiments have a conversion efficiency superior to presently available single and double conversion batteries. In addition, the devices of exemplary embodiments described herein may be incorporated into an apparatus for charging a secondary battery and/or powering an electrical load, such as a power-consumption device. The energy harvesting devices of exemplary embodiments described herein are a light weight, compact, and have a relatively long operating life with an electrical power output at a useful value. Furthermore, in addition to the tailored work functions, the nanoparticle clusters of exemplary embodiments described herein are multiphase nano-composites that include thermoelectric materials. The combination of thermoelectric and thermionic functions within a single device further enhances the power generation capabilities of the thermal energy harvesting thermionic devices.

The conversion of heat generated by the heat generating source into usable electricity enables energy harvesting capable of offsetting, or even replacing, the reliance of electronics on conventional power supplies, such as electrochemical batteries, especially when long-term operation of a large number of electronic devices in dispersed locations is required. Energy harvesting distinguishes itself from batteries and hardwire power owing to inherent advantages, such as outstanding longevity measured in years, little maintenance, and minimal disposal and contamination issues. The thermal energy harvesting thermionic devices described herein demonstrate a novel electric generator with low cost for efficiently harvesting thermal energy. The devices described herein initiate electron flow due to the differences in the Fermi levels of the electrodes without the need for an initial temperature differential or thermal gradient, although in exemplary embodiments heat generating sources are used to generate the temperature differentials over the course of use.

The thermal energy harvesting thermionic devices of exemplary embodiments described herein are scalable across a large number of power generation requirements. The devices may be designed for applications requiring electric power in the milliwatts (mW), watts (W), kilowatts (kW), and megawatts (MW) ranges.

Aspects of the present embodiments are described herein with reference to one or more of flowchart illustrations and/or block diagrams of methods and apparatus (systems) according to the embodiments.

While particular embodiments have been shown and described, it will be understood to those skilled in the art that, based upon the teachings herein, changes and modifications may be made without departing from its broader aspects. Therefore, the appended claims are to encompass within their scope all such changes and modifications as are within the true spirit and scope of the embodiments. Furthermore, it is to be understood that the embodiments are solely defined by the appended claims. It will be understood by those with skill in the art that if a specific number of an introduced claim element is intended, such intent will be explicitly recited in the claim, and in the absence of such recitation no such limitation is present. For non-limiting example, as an aid to understanding, the following appended claims contain usage of the introductory phrases “at least one” and “one or more” to introduce claim elements. However, the use of such phrases should not be construed to imply that the introduction of a claim element by the indefinite articles “a” or “an” limits any particular claim containing such introduced claim element to the embodiments containing only one such element, even when the same claim includes the introductory phrases “one or more” or “at least one” and indefinite articles such as “a” or “an”; the same holds true for the use in the claims of definite articles. As used herein, the term “and/or” means either or both (or any combination or all of the terms or expressed referred to).

The corresponding structures, materials, acts, and equivalents of all means or step plus function elements in the claims below are intended to include any structure, material, or act for performing the function in combination with other claimed elements as specifically claimed. The description of the present embodiments has been presented for purposes of illustration and description, but is not intended to be exhaustive or limited to the embodiments in the form disclosed. Many modifications and variations will be apparent to those of ordinary skill in the art without departing from the scope and spirit of the embodiments. The embodiments were chosen and described in order to best explain the principles of the embodiments and the practical application, and to enable others of ordinary skill in the art to understand the embodiments for various embodiments with various modifications and combinations with one another as are suited to the particular use contemplated. Accordingly, the scope of protection of the embodiment(s) is limited only by the following claims and their equivalents.

1. An apparatus comprising:
an electrical energy storage device;
a heat generating source operatively connected to the electrical energy storage device to convert electrical energy supplied by the electrical energy storage device to heat;
a thermal energy harvesting thermionic device proximal to the heat generating source, the thermal energy harvesting thermionic device to receive the heat from the heat generating source and generate an electrical output, the thermal energy harvesting thermionic device comprising:
a cathode;
an anode spaced from the cathode to provide an inter-electrode gap between the cathode and the anode; and
a plurality of nanoparticles suspended in a medium contained in the inter-electrode gap, the nanoparticles arranged in the inter-electrode gap to permit electron transfer between the cathode and the anode;
a temperature sensor configured to monitor a temperature of the thermal energy harvesting thermionic device; and
a controller operatively connected to the electrical energy storage device and the temperature sensor, the controller to activate the electrical energy storage device to supply the stored electrical energy to the heat generating source in response to the temperature of the thermal energy harvesting thermionic device, as measured by the temperature sensor, falling below a threshold temperature.

2. The apparatus of claim 1, further comprising a rechargeable power storage device operatively connected to the thermal energy harvesting thermionic device to receive the electrical output to recharge the rechargeable power storage device.

3. The apparatus of claim 2, wherein the rechargeable power storage device comprises a rechargeable battery.

4. The apparatus of claim 2, further comprising a heat dissipating device positioned between the thermal energy harvesting thermionic device and the rechargeable power storage device.

5. The apparatus of claim 1, wherein the electrical energy storage device comprises a capacitor.

6. The apparatus of claim 1, wherein the heat generating source comprises a resistor.

7. The apparatus of claim 1, wherein the temperature sensor comprises a thermocouple.

8. The apparatus of claim 1, further comprising a housing comprised of aerogel, the housing containing the electrical energy storage device, the heat generating source, the thermal energy harvesting thermionic device, the temperature sensor, and the controller.

9. The apparatus of claim 1, further comprising a power-consumption device operatively connected to the thermal energy harvesting thermionic device, the power-consumption device to receive the electrical output from the thermal energy harvesting thermionic device.

10. The apparatus of claim 1, wherein the thermal energy harvesting thermionic device comprises a plurality of serially connected thermal energy harvesting thermionic devices.

11. The apparatus of claim 1, wherein the thermal energy harvesting thermionic device comprises a nano-scale component.

12. An apparatus comprising:
a photovoltaic cell configured to convert light energy into electrical energy;
a heat generating source operatively connected to the photovoltaic cell to convert the electrical energy supplied by the photovoltaic cell to heat;
a thermal energy harvesting thermionic device proximal to the heat generating source, the thermal energy harvesting thermionic device to receive the heat from the heat generating source and generate an electrical output, the thermal energy harvesting thermionic device comprising:
a cathode;
an anode spaced from the cathode to provide an inter-electrode gap between the cathode and the anode; and
a plurality of nanoparticles suspended in a medium contained in the inter-electrode gap, the nanoparticles arranged in the inter-electrode gap to permit electron transfer between the cathode and the anode;
a temperature sensor configured to monitor a temperature of the thermal energy harvesting thermionic device; and
a controller operatively connected to the photovoltaic cell and the temperature sensor, the controller to activate the photovoltaic cell to supply the electrical energy to the heat generating source in response to the temperature of the thermal energy harvesting thermionic device, as measured by the temperature sensor, falling below a threshold temperature.

13. The apparatus of claim 12, further comprising a rechargeable power storage device operatively connected to the thermal energy harvesting thermionic device to receive the electrical output to recharge the rechargeable power storage device.

14. The apparatus of claim 13, wherein the rechargeable power storage device comprises a rechargeable battery.

15. The apparatus of claim 13, further comprising a heat dissipating device positioned between the thermal energy harvesting thermionic device and the rechargeable power storage device.

16. The apparatus of claim 12, wherein the heat generating source comprises a resistor.

17. The apparatus of claim 12, wherein the temperature sensor comprises a thermocouple.

18. The apparatus of claim 12, further comprising a housing comprised of aerogel, the housing containing the electrical energy storage device, the heat generating source, the thermal energy harvesting thermionic device, the temperature sensor, and the controller.

19. The apparatus of claim 12, further comprising a power-consumption device operatively connected to the thermal energy harvesting thermionic device, the power-consumption device to receive the electrical output from the thermal energy harvesting thermionic device.

20. The apparatus of claim 12, wherein the thermal energy harvesting thermionic device comprises a plurality of serially connected thermal energy harvesting thermionic devices.

21. The apparatus of claim 12, wherein the thermal energy harvesting thermionic device comprises a nano-scale component.

22. A method, comprising:
supplying electrical energy to a heat generating source to convert the electrical to heat;
heating a thermal energy harvesting thermionic device proximal to the heat generating source to receive the heat from the heat generating source and generating an electrical output, the thermal energy harvesting thermionic device comprising:
a cathode;
an anode spaced from the cathode to provide an inter-electrode gap between the cathode and the anode; and
a plurality of nanoparticles suspended in a medium contained in the inter-electrode gap, the nanoparticles arranged in the inter-electrode gap to permit electron transfer between the cathode and the anode;
monitoring a temperature of the thermal energy harvesting thermionic device; and
activating a source of the electrical energy to supply the electrical energy to the heat generating source in response to the temperature of the thermal energy harvesting thermionic device, as measured by the temperature sensor, falling below a threshold temperature.

23. The method of claim 22, further comprising providing electrical energy storage device configured to supply the electrical energy to the heat generating source.

24. The method of claim 22, further comprising providing a photovoltaic cell configured to convert light energy to the electrical energy for feeding to the heat generating source.
